(19) United States
(12) Patent Application Publication
(10) Pub. No.: US 2025/0145887 A1
(43) Pub. Date: May 8, 2025

(54) SINTERED BODY AND LIGHT EMITTING DEVICE

(71) Applicant: NICHIA CORPORATION, Anan-shi (JP)

(72) Inventors: Teruhiko NOGUCHI, Anan-shi (JP); Toshiyuki HIRAI, Komatsushima-shi (JP); Shimpei KINOSHITA, Anan-shi (JP)

(73) Assignee: NICHIA CORPORATION, Anan-shi (JP)

(21) Appl. No.: 18/936,924

(22) Filed: Nov. 4, 2024

(30) Foreign Application Priority Data
Nov. 6, 2023 (JP) 2023-189157

(51) Int. Cl. C09K 11/77; H01L 33/32; H01L 33/50

(52) U.S. Cl. CPC C09K 11/77347; H10H 20/8512; H10H 20/825

(57) ABSTRACT

A sintered body contains a fluorescent material being at least one selected from the group consisting of a nitride fluorescent material having a composition of formula (I) and an α-SiAlON fluorescent material having a composition of formula (II), and emits light having a color tone in an area A1 surrounded by lines connecting a point 1a (x=0.549, y=0.425), a point 2a (x=0.562, y=0.438), a point 3a (x=0.589, y=0.411), and a point 4a (x=0.576, y=0.407) in the chromaticity diagram of the CIE 1931 color system upon irradiation with excitation light, wherein, upon irradiation with excitation light, the light emitted from the sintered body has an emission spectrum in which an integral value ratio Z2/Z1 as described in the disclosure is 0.005 or more.

### CROSS-REFERENCE TO RELATED PATENT APPLICATION

This application claims priority to Japanese Patent Application No. 2023-189157, filed on Nov. 6, 2023, the disclosure of which is hereby incorporated by reference in its entirety.

### BACKGROUND

### Technical Field

The present disclosure relates to a sintered body and a light emitting device.

### Description of Related Art

There are light emitting devices using a light emitting element such as a light emitting diode (LED) or a laser diode (LD), in which a light emitting element serving as an excitation light source and a member containing a fluorescent material that absorbs a part of light emitted from the light emitting element and converts its wavelength to a different wavelength are combined. The light emitting devices emit a mixed color light of light emitted from the light emitting element and light emitted from the fluorescent material. Such light emitting devices are used for applications such as on-vehicle lighting, general lighting, backlighting for liquid crystal display devices, illuminations, and light sources for projectors.

As a member containing a fluorescent material, International Unexamined Patent Publication No. 2016/117623 discloses a sintered body containing a fluoride inorganic binder and a nitride fluorescent material.

### SUMMARY

In the sintered body containing a fluoride inorganic binder and a nitride fluorescent material, the fluoride inorganic binder and the nitride fluorescent material may react with each other during calcination. The sintered body containing the nitride fluorescent material reacted with the fluoride inorganic binder may emit light having a lower luminous flux and lower light emission characteristics upon irradiation with excitation light.

One object of the present disclosure is to provide a sintered body that emits light having a high luminous flux upon irradiation with excitation light, and a light emitting device using the same.

According to a first aspect of the present disclosure, a sintered body may contain: a fluorescent material being at least one selected from the group consisting of a nitride fluorescent material having a composition represented by the following formula (I) and an α-SiAlON fluorescent material having a composition represented by the following formula (II),

(Ba_{1-u-w}M¹ᵤM²_{w})₂Si₅N₈ (I),
wherein M¹ represents at least one element selected from the group consisting of Sr, Ca, and Mg, M² represents at least one element selected from the group consisting of Eu, Ce, Tb, and Mn, and u and w satisfy 0<u≤0.5 and 0.001≤w<0.5; and

M³_{q}Si₁₂₋₍ᵣ₊ₛ₎Alᵣ₊ₛOₛN₁₆₋ₛ:Euₜ (II),
wherein M³ represents at least one element selected from the group consisting of Li, Mg, Ca, Sr, Y, and lanthanide elements (excluding La and Ce), and q, r, s, and t satisfy 0<q≤2.0, 2.0≤r≤6.0, 0≤s≤1.0, and 0.001≤t≤0.5. The sintered body is configured to emit light having a color in an area A1 in the chromaticity diagram of the CIE 1931 color system upon irradiation with excitation light, the area A1 being defined by a first straight line connecting a point 1a and a point 2a, a second straight line connecting the point 2a and a point 3a, a third straight line connecting the point 3a and a point 4a, and a fourth straight line connecting the point 4a and the point 1a, wherein the point 1a, the point 2a, the point 3a, and the point 4a have chromaticity coordinates (x, y) being (x=0.549, y=0.425), (x=0.562, y=0.438), (x=0.589, y=0.411), and (x=0.576, y=0.407), respectively, in the chromaticity diagram of the CIE 1931 color system. Upon irradiation with excitation light having a light emission peak wavelength that is 450 nm and an output that is 1,300 mW/mm² or more and 6,000 mW/mm² or less, the sintered body emits light including light wavelength-converted from the excitation light by the fluorescent material contained in the sintered body and the excitation light transmitted through the sintered body, and the light emitted from the sintered body having a light emission spectrum in which an integral value ratio Z2/Z1 of a second integral value Z2 of light emission intensities in a wavelength range of 400 nm or more and 500 nm or less to a first integral value Z1 of light emission intensities in a wavelength range of more than 500 nm and 800 nm or less is 0.005 or more.

According to a second aspect of the present disclosure, a light emitting device may include an excitation light source emitting light having a light emission peak wavelength of 380 nm or more and 570 nm or less, and the sintered body, which may be positioned at a location to be irradiated with light emitted from the excitation light source.

According to certain aspects of the present disclosure, a sintered body that emits light having a high luminous flux upon irradiation with excitation light and a light emitting device using the same can be provided.

### BRIEF DESCRIPTION OF THE DRAWINGS

FIG. 1 is a graph showing an example of a light emission spectrum of light emitted from a sintered body upon irradiation with excitation light.

FIG. 2 is a chromaticity diagram of the CIE1931 color system showing an area A that satisfies the amber color requirements in the ECE standard.

FIG. 3 is a chromaticity diagram of the CIE1931 color system showing an area A1 of light emitted from a sintered body irradiated with excitation light.

FIG. 4 is a chromaticity diagram of the CIE1931 color system showing an area A2 of light emitted from a sintered body irradiated with excitation light.

FIG. 5 is a chromaticity diagram of the CIE1931 color system showing an area A3 of light emitted from a sintered body irradiated with excitation light.

FIG. 6 is a chromaticity diagram of the CIE1931 color system showing the areas A, A1, A2, and A3.

FIG. 7 is a schematic plan view showing an example of a light emitting device according to the present disclosure.

FIG. 8 is a schematic cross-sectional view showing an example of a light emitting device according to the present disclosure.

FIG. 9 is an SEM micrograph of a nitride fluorescent material 5 according to the present disclosure.

FIG. 10 is a chromaticity diagram of the CIE1931 color system showing the areas A1, A2, and A3, as well as the chromaticity coordinates (x, y) of light emitted from a light emitting device using a sintered body according to each of Examples 1-1 to 1-3.

FIG. 11 is a chromaticity diagram of the CIE1931 color system showing the areas A1, A2, and A3, as well as the chromaticity coordinates (x, y) of light emitted from a light emitting device using a sintered body according to each of Examples 2-1 to 2-5 and Comparative Example 2-6.

FIG. 12 is a chromaticity diagram of the CIE1931 color system showing the areas A1, A2, and A3, as well as the chromaticity coordinates (x, y) of light emitted from a light emitting device using a sintered body according to each of Examples 3-1 to 3-3.

FIG. 13 is a chromaticity diagram of the CIE1931 color system showing the areas A1, A2, and A3, as well as the chromaticity coordinates (x, y) of light emitted from a light emitting device using a sintered body according to each of Examples 4-1 to 4-3 and Comparative Examples 4-4 and 4-5.

FIG. 14 is a chromaticity diagram of the CIE1931 color system showing the areas A1, A2, and A3, as well as the chromaticity coordinates (x, y) of light emitted from a light emitting device using a sintered body according to each of Examples 5-1 to 5-4.

FIG. 15 is an SEM micrograph of the fractured surface of the sintered body according to Example 5-1.

FIG. 16 is a chromaticity diagram of the CIE1931 color system showing the areas A1, A2, and A3, as well as the chromaticity coordinates (x, y) of light emitted from a light emitting device using a sintered body according to each of Examples 6-1 to 6-4.

### DETAILED DESCRIPTION

The following describes a sintered body and a light emitting device according to the present disclosure. Embodiments described below are exemplifications for giving a concrete form to the technical idea of the present disclosure, and the present invention is not limited to the following sintered body and light emitting device. The relationships between color names and chromaticity coordinates, and the relationships between wavelength ranges of light and color names of monochromatic lights in the present specification are in accordance with Japanese Industrial Standard (JIS) Z8110. In this specification, the “fluorescent material” is used in the same meaning as a “fluorescent phosphor”.

The sintered body contains a fluorescent material being at least one selected from the group consisting of a nitride fluorescent material having a composition represented by the following formula (I) and an α-SiAlON fluorescent material having a composition represented by the following formula (II) and emits light having a color in an area A1 in the chromaticity diagram of the CIE 1931 color system upon irradiation with excitation light, the area A1 being defined by a first straight line connecting a point 1a and a point 2a, a second straight line connecting the point 2a and a point 3a, a third straight line connecting the point 3a and a point 4a, and a fourth straight line connecting the point 4a and the point 1a when the chromaticity coordinates (x, y) of (x=0.549, y=0.425), (x=0.562, y=0.438), (x=0.589, y=0.411), and (x=0.576, y=0.407) are defined as the point 1a, the point 2a, the point 3a, and the point 4a, respectively, wherein, upon irradiation with excitation light having a light emission peak wavelength of 450 nm and an output of 1,300 mW/mm² or more and 6,000 mW/mm² or less, the sintered body emits light including light wavelength-converted from the excitation light by the fluorescent material contained in the sintered body and the excitation light transmitted through the sintered body, the light emitted from the sintered body having a light emission spectrum in which an integral value ratio Z2/Z1 of a second integral value Z2 of light emission intensities in a wavelength range of 400 nm or more and 500 nm or less to a first integral value Z1 of light emission intensities in a wavelength range of more than 500 nm and 800 nm or less is 0.005 or more.

When the sintered body is irradiated with excitation light having a light emission peak wavelength of 450 nm and an output of 1,300 mW/mm² or more and 6,000 mW/mm² or less, the sintered body emits light including light having been wavelength converted from the excitation light by the fluorescent material contained in the sintered body and the excitation light transmitted through the sintered body. In the light emission spectrum of the light emitted from the sintered body, the light emission spectrum within the wavelength range of more than 500 nm and 800 nm or less represents the light emission spectrum of the light having been wavelength-converted from the excitation light by the fluorescent material contained in the sintered body upon irradiation with the excitation light, and the light emission spectrum within the wavelength range of 400 nm or more and 500 nm or less represents the light emission spectrum of the excitation light transmitted through the sintered body. The sintered body, upon irradiation with excitation light having a light emission peak wavelength of 450 nm and an output of 1,300 mW/mm² or more and 6,000 mW/mm² or less, emits light having the light emission spectrum in which the integral value ratio Z2/Z1 of the second integral value Z2 of light emission intensities in the wavelength range of 400 nm or more and 500 nm or less to the first integral value Z1 of light emission intensities in the wavelength range of more than 500 nm and 800 nm or less is 0.005 or more. The sintered body irradiated with the excitation light emits light including light having been wavelength-converted from the excitation light by the fluorescent material contained in the sintered body and excitation light that has been irradiated to, dispersed within, and transmitted through the sintered body, and thus emits light having a color within the area A1 and a high luminous flux. It is assumed that increase in size of the fluorescent material particles in the sintered body reduces the interfaces within the sintered body composed of the fluorescent material particles and thus increases the light extraction efficiency, which causes the sintered body irradiated with the excitation light to emit light having a light emission spectrum in which an integral value ratio Z2/Z1 of 0.005 or more and a high luminous flux.

The sintered body, when irradiated with excitation light having a light emission peak wavelength of 450 nm and an output of 1,300 mW/mm² or more and 6,000 mW/mm² or less, emits light including the light having been wavelength-converted from the excitation light by the fluorescent material contained in the sintered body and the excitation light transmitted through the sintered body, and the light emitted from the sintered body has a light emission spectrum in which the integral value ratio Z2/Z1 of the second integral value Z2 of light emission intensities in the wavelength range of 400 nm or more and 500 nm or less to the first integral value Z1 of light emission intensities in the wavelength range of more than 500 nm and 800 nm or less is preferably 0.008 or more, more preferably 0.009 or more, and even more preferably 0.01 or more. When irradiated with the excitation light, the sintered body may emit light having a light emission spectrum in which an integral value ratio Z2/Z1 of 0.04 or less, and preferably emits light having a light emission spectrum in which an integral value ratio Z2/Z1 is 0.005 or more and 0.04 or less, more preferably 0.008 or more and 0.04 or less, and even more preferably 0.01 or more and 0.04 or less. The sintered body may emit, upon irradiation with the excitation light, light having an light emission spectrum in which an integral value ratio Z2/Z1 is 0.03 or less, or of 0.02 or less. When the sintered body emits light having the light emission spectrum with a large integral value ratio Z2/Z1 of more than 0.04 upon irradiation with the excitation light, excitation light on the short wavelength side transmitted through the sintered body is excessively increased, so that light not having a color within the area A1 is emitted from the sintered body.

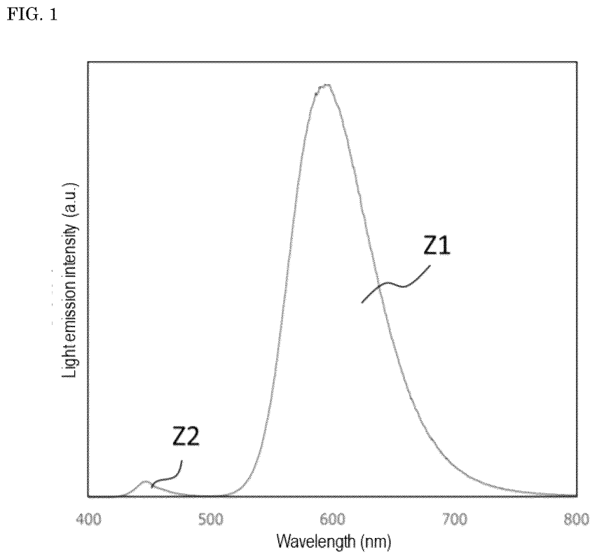

FIG. 1 is a graph showing an example of a light emission spectrum of light emitted from a sintered body upon irradiation with excitation light having a light emission peak wavelength of 450 nm and an output of 1,300 mW/mm² or more and 6,000 mW/mm² or less, the light emitted from the sintered body including light having been wavelength-converted from the excitation light by the fluorescent material contained in the sintered body and the excitation light transmitted through the sintered body.

In the light emission spectrum of the light emitted from the sintered body upon irradiation with excitation light, the light emitted from the sintered body including light having been wavelength-converted from the excitation light by the fluorescent material contained in the sintered body and the excitation light transmitted through the sintered body, as shown in FIG. 1, the first integral value Z1 within the wavelength range of more than 500 nm and 800 nm or less is the integral value of the light emission intensities in the wavelength width range surrounded by the horizontal axis where the light emission intensity (a.u. (arbitrary unit)) is 0 (zero) and by the light emission spectrum of the sintered body in the wavelength range of more than 500 nm and 800 nm or less. In the light emission spectrum of the light emitted from the sintered body as shown in FIG. 1, the second integral value Z2 within the wavelength range of 400 nm or more and 500 nm or less is the integral value of the light emission intensities in the wavelength width range surrounded by the horizontal axis where the light emission intensity (a.u.) is 0 and by the light emission spectrum of the light emitted from the sintered body in the wavelength range of 400 nm or more and 500 nm or less. In the case where, in the light emission spectrum of the light emitted from the sintered body upon irradiation with excitation light, the light emission spectrum of the light emitted from the sintered body in the wavelength range of more than 500 nm and 800 nm or less does not intersect the horizontal axis where the light emission intensity is 0, the first integral value Z1 is the integral value of the light emission intensities in the wavelength width range surrounded by a straight line extending vertically from the wavelength of 500 nm on the horizontal axis where the light emission intensity is 0, a straight line extending vertically from the wavelength of 800 nm on the horizontal axis where the light emission intensity is 0, the horizontal axis where the light emission intensity is 0, and the light emission spectrum of the light emitted from the sintered body in the wavelength range of more than 500 nm and 800 nm or less. In the case where, in the light emission spectrum of the light emitted from the sintered body upon irradiation with excitation light, the light emission spectrum of the light emitted from the sintered body in the wavelength range of 400 nm or more and 500 nm or less does not intersect the horizontal axis where the light emission intensity is 0, the second integral value Z2 is the integral value of the light emission intensities in the wavelength width range surrounded by a straight line extending vertically from the wavelength of 400 nm on the horizontal axis where the light emission intensity is 0, a straight line extending vertically from the wavelength of 500 nm on the horizontal axis where the light emission intensity is 0, the horizontal axis where the light emission intensity is 0, and the light emission spectrum of the light emitted from the sintered body in the wavelength range of 400 nm or more and 500 nm or less.

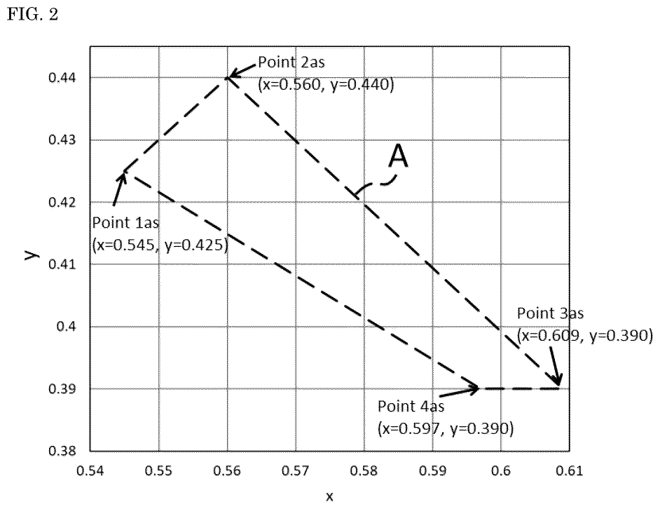

In the chromaticity diagram of the CIE (Commission Internationale de l'Eclairage) 1931 color system, the area A1 is the color of light within the area A that satisfies the requirements for amber (orange) color specified in the ECE (United Nations Economic Commission for Europe) standard. In the present specification, amber color includes orange. The light having a color within the area A that satisfies the amber color requirements specified in the ECE standard is emitted from direction indicators (turn signal lamps or blinkers) in a vehicle lamp such as a rear combination lamp mounted on vehicles. When the chromaticity coordinates (x, y) of (x=0.545, y=0.425), (x=0.560, y=0.440), (x=0.609, y=0.390), and (x=0.597, y=0.390) are respectively a point 1as, a point 2as, a point 3as, and a point 4as in the chromaticity diagram of the CIE 1931 color system, the area A that satisfies the amber color requirements specified in the ECE standard is surrounded by a straight line 1s connecting the point 1as and the point 2as, a straight line 2s connecting the point 2as and the point 3as, a straight line 3s connecting the point 3as and the point 4as, and a straight line 4s connecting the point 4as and the point 1as. FIG. 2 is a chromaticity diagram of the CIE1931 color system showing the area A that satisfies the amber color requirements specified in the ECE standard. Table 1 shows the chromaticity coordinates of the point 1as, the point 2as, the point 3as, and the point 4as, which indicate the area A.

TABLE 1

Area A
Chromaticity coordinates

| | x | y |
|---|---|---|
| Point 1as | 0.545 | 0.425 |
| Point 2as | 0.560 | 0.440 |
| Point 3as | 0.609 | 0.390 |
| Point 4as | 0.597 | 0.390 |

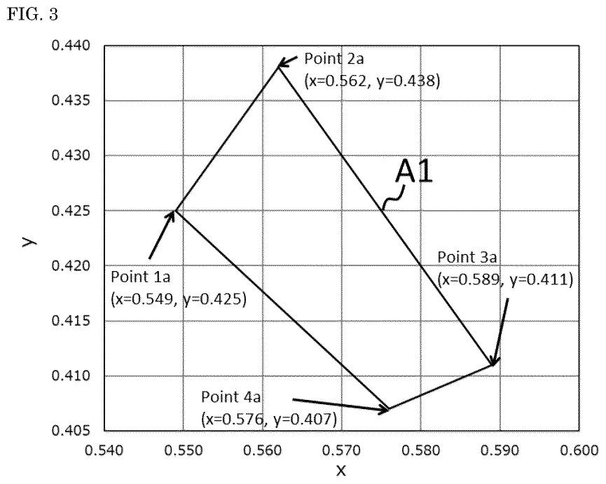

The sintered body, when irradiated with excitation light, emits light including light that has been wavelength-converted from the excitation light by the fluorescent material contained in the sintered body and the excitation light transmitted through the sintered body, and the light emitted from the sintered body has a color within an area A1 in the chromaticity diagram of the CIE1931 color system, wherein when the chromaticity coordinates (x, y) of (x=0.549, y=0.425), (x=0.562, y=0.438), (x=0.589, y=0.411), and (x=0.576, y=0.407) are defined as a point 1a, a point 2a, a point 3a, and a point 4a, respectively, the area A1 is surrounded by a first straight line connecting the point 1a and the point 2a, a second straight line connecting the point 2a and the point 3a, a third straight line connecting the point 3a and the point 4a, and a fourth straight line connecting the point 4a and the point 1a. FIG. 3 is a chromaticity diagram of the CIE1931 color system showing the area A1. Table 2 shows the chromaticity coordinates of the point 1a, the point 2a, the point 3a, and the point 4a, which indicate the area A1.

TABLE 2

Area A1
Chromaticity coordinates

| | x | y |
|---|---|---|
| Point 1a | 0.549 | 0.425 |
| Point 2a | 0.562 | 0.438 |
| Point 3a | 0.589 | 0.411 |
| Point 4a | 0.576 | 0.407 |

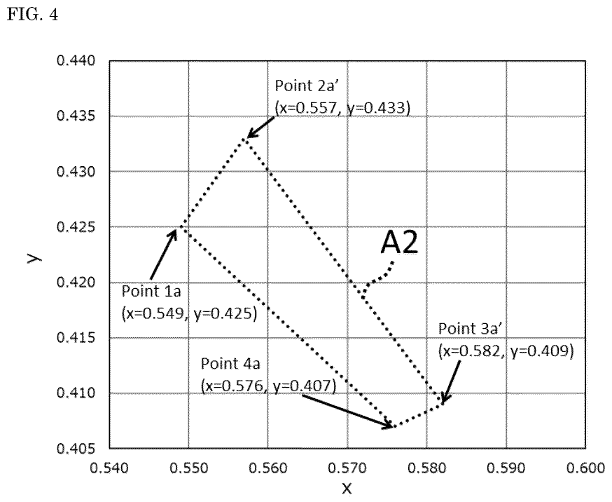

The sintered body, when irradiated with excitation light, emits light including light that has been wavelength converted from the excitation light by the fluorescent material contained in the sintered body and the excitation light transmitted through the sintered body, and it is preferred that the light emitted from the sintered body has a color within an area A2 in the chromaticity diagram of the CIE1931 color system, wherein when the chromaticity coordinates (x, y) are (x=0.549, y=0.425), (x=0.557, y=0.433), (x=0.582, y=0.409), and (x=0.576, y=0.407) are defined as a point 1a, a point 2a′, a point 3a′, and a point 4a, respectively, the area A2 is surrounded by a fifth straight line connecting the point 1a and the point 2a′, a sixth straight line connecting the point 2a′ and the point 3a′, a seventh straight line connecting the point 3a′ and the point 4a, and a eighth straight line connecting the point 4a and the point 1a. When the light having a color within the area A2 is emitted from the sintered body, emission of light on the shorter wavelength side within the color range of the area A1 is increased. FIG. 4 is a chromaticity diagram of the CIE1931 color system showing the area A2. Table 3 shows the chromaticity coordinates of the point 1a, the point 2a′, the point 3a′, and the point 4a, which indicate the area A2.

TABLE 3

Area A2
Chromaticity coordinates

| | x | y |
|---|---|---|
| Point 1a | 0.549 | 0.425 |
| Point 2a′ | 0.557 | 0.433 |
| Point 3a′ | 0.582 | 0.409 |
| Point 4a | 0.576 | 0.407 |

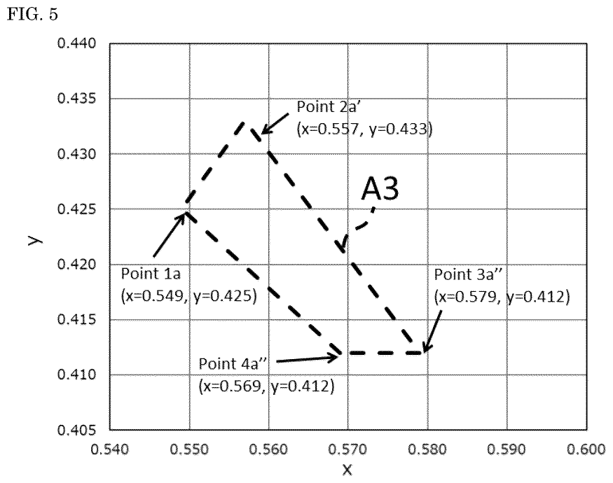

The sintered body, when irradiated with excitation light, emits light including light obtained by wavelength-converting the excitation light by the fluorescent material contained in the sintered body and the excitation light transmitted through the sintered body, and it is preferred that the light emitted from the sintered body has a color within an area A3 in the chromaticity diagram of the CIE1931 color system, wherein when the chromaticity coordinates (x, y) of (x=0.549, y=0.425), (x=0.557, y=0.433), (x=0.579, y=0.412), and (x=0.569, y=0.412) are defined as a point 1a, a point 2a′, a point 3a″, and a point 4a″, respectively, the area A3 is surrounded by a ninth straight line connecting the point 1a and the point 2a′, a tenth straight line connecting the point 2a′ and the point 3a″, a eleventh straight line connecting the point 3a″ and the point 4a″, and a twelfth straight line connecting the point 4a″ and the point 1a. When the light having a color within the area A3 is emitted from the sintered body, more light is emitted on the shorter wavelength side within the color ranges of the areas A1 and A2. FIG. 5 is a chromaticity diagram of the CIE1931 color system showing the area A3. Table 4 shows the chromaticity coordinates of the point 1a, the point 2a′, the point 3a″, and the point 4a″, which indicate the area A3.

TABLE 4

Area A3
Chromaticity coordinates

| | x | y |
|---|---|---|
| Point 1a | 0.549 | 0.425 |
| Point 2a′ | 0.557 | 0.433 |
| Point 3a″ | 0.579 | 0.412 |
| Point 4a″ | 0.569 | 0.412 |

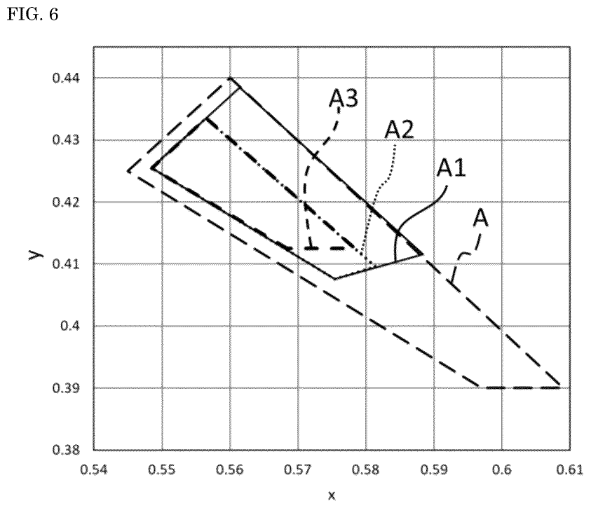

FIG. 6 is a chromaticity diagram of the CIE1931 color system showing the area A that satisfies the amber color requirements specified in the ECE standard, and the areas A1, A2, and A3. The areas A1, A2, and A3 are within the area A that satisfies the amber color requirements specified in the ECE standard, and are the areas that have colors on the shorter wavelength side within the area A. The area A2 is on the area to the left of the sixth straight line connecting the point 2a′ (x=0.557, y=0.433) and the point 3a′ (x=0.582, y=0.409) within the are A1 in the chromaticity diagram of the CIE1931 color system. The area A3 has a color on the shorter wavelength side than the areas A1 and A2.

The sintered body contains a fluorescent material being at least one selected from the group consisting of a nitride fluorescent material having a composition represented by the following formula (I) and an α-SiAlON fluorescent material having a composition represented by the following formula (II):

(Ba_{1-u-w}M¹ᵤM²_{w})₂Si₅N₈ (I),
wherein M¹ represents at least one element selected from the group consisting of Sr, Ca, and Mg, M² represents at least one element selected from the group consisting of Eu, Ce, Tb, and Mn, and u and w satisfy 0<u≤0.5 and 0.001≤w<0.5; and

M³_{q}Si₁₂₋₍ᵣ₊ₛ₎Alᵣ₊ₛOₛN₁₆₋ₛ:Euₜ (II)
wherein M³ represents at least one element selected from the group consisting of Li, Mg, Ca, Sr, Y, and lanthanide elements (excluding La and Ce), and q, r, s, and t satisfy 0<q≤2.0, 2.0≤r≤6.0, 0≤s≤1.0, and 0.001≤t≤0.5.

It is preferred that the sintered body contains only a fluorescent material being at least one selected from the group consisting of a nitride fluorescent material having a composition represented by the formula (I) and an α-SiAlON fluorescent material having a composition represented by the formula (II), and does not contain any other fluorescent material having a composition different from that represented by the formula (I) or (II). The sintered body may contain only a nitride fluorescent material having a composition represented by the formula (I). The sintered body may contain both a nitride fluorescent material having a composition represented by the formula (I) and an α-SiAlON fluorescent material having a composition represented by the formula (II).

In the composition of the nitride fluorescent material represented by the formula (I), the element M¹ is an element constituting, together with Ba, the crystal structure of the host crystal. In 1 mol of the composition of the nitride fluorescent material represented by the formula (I), the molar ratio of the element M¹ is represented by the product of 2 and the parameter u. In the formula (I), the parameter u is more than 0 and 0.5 or less (0<u≤0.5), may be 0.1 or more and 0.48 or less (0.1≤u≤0.48), may be 0.2 or more and 0.45 or less (0.2≤u≤0.45), and preferably 0.25 or more and 0.45 or less (0.25≤u≤0.45). In the composition of the nitride fluorescent material, the molar ratio of the element M¹ constituting, together with Ba, the crystal structure of the host crystal affects the light emission characteristics, including the luminous flux, and color of the sintered body irradiated with excitation light. In the composition of the nitride fluorescent material represented by the formula (I), when the parameter u in the product of 2 and the parameter u, which represents the molar ratio of the element M¹, is more than 0 and 0.5 or less, preferably 0.25 or more and 0.45 or less, the irradiated excitation light is wavelength-converted by the nitride fluorescent material, and the sintered body containing the nitride fluorescent material emits light including the light wavelength-converted from the excitation light by the fluorescent material contained in the sintered body and the excitation light transmitted through the sintered body, the light emitted from the sintered body having a color within the area A1 and having an emission spectrum in which an integral value ratio Z2/Z1 is 0.005 or more.

In the composition of the nitride fluorescent material represented by the formula (I), the element M² is an activating element. In 1 mol of the composition of the nitride fluorescent material represented by the formula (I), the molar ratio of the activating element M² is represented by the product of 2 and the parameter w. In the formula (I), the parameter w is 0.001 or more and less than 0.5 (0.001≤w<0.5), may be 0.001 or more and less than 0.1 (0.001≤w<0.1), may be 0.001 or more and less than 0.05 (0.001≤w<0.05), may be 0.001 or more and less than 0.01 (0.001≤w<0.01), may be 0.001 or more and less than 0.005 (0.001≤w<0.005), may be 0.001 or more and less than 0.0035 (0.001≤w<0.0035), or may be 0.001 or more and less than 0.0025 (0.001≤w<0.0025). In the composition of the nitride fluorescent material, the molar ratio of the activating element affects the light emission characteristics, including the luminous flux, and an emission color of the sintered body irradiated with excitation light. When the molar ratio of the element M² as the activating element in the composition represented by the formula (I) is high, the light emission intensity of the nitride fluorescent material upon irradiation with excitation light increases. The sintered body containing a fluorescent material having a high light emission intensity upon irradiation with excitation light can be formed into a sintered body having a small thickness. With a small thickness of the sintered body, light can be easily extracted in the thickness direction of the sintered body. In the present specification, the sintered body having a thin thickness refers specifically to the case where the thickness of a sintered body composed only of a nitride fluorescent material in which, in the composition represented by the formula (I), the element M² as the activating element is Eu, and the parameter w in the product of 2 and the parameter w, which represents the molar ratio of Eu, is 0.001 or more and less than 0.5, is 80 μm or less. When excitation light is irradiated to the sintered body having a thin thickness, the sintered body emits light including light that has been wavelength-converted from the excitation light by the fluorescent material contained in the sintered body having a thin thickness and the excitation light transmitted through the sintered body, and the light emitted from the sintered body has a color within the area A1, and has an emission spectrum in which an integral value ratio Z2/Z1 is 0.005 or more. When the molar ratio of the element M² as the activating element in the composition represented by the formula (I) is low, the light emission intensity of the nitride fluorescent material upon irradiation with excitation light is low. The sintered body containing a fluorescent material having a low light emission intensity upon irradiation with excitation light can be formed into a sintered body having a thick thickness. With a large thickness of the sintered body, the sintered body can have high mechanical strength. In the present specification, as one specific example, when the thickness of a sintered body composed only of a nitride fluorescent material in which, in the composition represented by the formula (I), the element M² as the activating element is Eu, and the parameter w in the product of 2 and the parameter w, which represents the molar ratio of Eu, is 0.001 or more and less than 0.5, is more than 220 μm, the sintered body has a large thickness. The sintered body having a thick thickness, upon irradiation with excitation light, emits light including light wavelength-converted from the excitation light by the fluorescent material contained in the sintered body having a large thickness and the excitation light transmitted through the sintered body, and the light emitted from the sintered body has a color within the area A, and has light emission spectrum in which an integral value ratio Z2/Z1 is 0.005 or more. However, when the thickness of the sintered body is excessively large, for example, more than 300 μm, the excitation light transmitted through the sintered body is decreased, and the integral value ratio Z2/Z1 in the light emission spectrum of the light emitted from the sintered body including the light wavelength-converted from the excitation light by the fluorescent material contained in the sintered body and the excitation light transmitted through the sintered body may be less than 0.005, so that light having a low relative luminous flux may be emitted. For this reason, the thickness of the sintered body is preferably 300 μm or less.

The nitride fluorescent material having a composition represented by the formula (I) may have a composition represented by the following formula (I-1) including Eu as the element M²:

(Ba_{1-u-w}M¹ᵤEu_{w})₂Si₅N₈ (I-1),
wherein M¹ represents at least one element selected from the group consisting of Sr, Ca, and Mg, and u and w satisfy 0<u≤0.5 and 0.001≤w<0.5.

The nitride fluorescent material having a composition represented by the formula (I) may have a composition represented by the following formula (I-2) including Sr as the element M¹:

(Ba_{1-u-w}SrᵤM²_{w})₂Si₅N₈ (I-2),
wherein M² represents at least one element selected from the group consisting of Eu, Ce, Tb, and Mn, and u and w satisfy 0<u≤0.5 and 0.001≤w<0.5.

The nitride fluorescent material having a composition represented by the formula (I) may have a composition represented by the following formula (I-3) including Sr as the element M¹ and Eu as the element M²:

(Ba_{1-u-w}SrᵤEu_{w})₂Si₅N₈ (I-3),
wherein u and w satisfy 0<u≤0.5 and 0.001≤w<0.5.

The sintered body preferably has a relative density of 97% or more. When the relative density of the sintered body is 97% or more, the sintered body containing only a fluorescent material being at least one selected from the group consisting of a nitride fluorescent material having a composition represented by the formula (I) and an α-SiAlON fluorescent material having a composition represented by the formula (II) emits light having a color within the area A1 upon irradiation with excitation light. The relative density of the sintered body is preferably 99.7% or less, more preferably 99.5% or less. When the relative density of the sintered body is 99.7% or less, the void ratio is a value obtained by subtracting the relative density from 100%. When the relative density of the sintered body is 97% or more, scattering of light due to voids in the sintered body can be reduced, light extraction can be increased, and light emitted from the sintered body including light wavelength-converted from the excitation light by the fluorescent material contained in the sintered body and the excitation light transmitted through the sintered body has a light emission spectrum in which an integral value ratio Z2/Z1 is 0.005 or more, so that light having a high luminous flux can be emitted.

It is preferred that the sintered body contains only a nitride fluorescent material and has a relative density of 97% or more and 99.7% or less. When the sintered body contains only a nitride fluorescent material and has a relative density of 97% or more and 99.7% or less, the sintered body emits light having: a color within the area A1; an emission spectrum in which an integral value ratio Z2/Z1 is 0.005 or more as light including light wavelength-converted from the excitation light by the fluorescent material contained in the sintered body and the excitation light transmitted through the sintered body; and a high luminous flux.

The relative density of the sintered body refers to a value calculated based on an apparent density of the sintered body relative to a true density of the sintered body. The relative density of the sintered body can be calculated according to the following calculation formula (1).

$$Relative density ( \% ) of sintered body = \frac{Apparent density of sintered body}{True density of sintered body} \times 100 \qquad ( 1 )$$

The true density of the sintered body refers to a value obtained by multiplying a mass ratio (% by mass) of the fluorescent material by a true density of the fluorescent material, relative to 100% by mass of the sintered body. When the sintered body is formed from a molded body composed only of a fluorescent material having one type of composition, the true density of the fluorescent material is the true density of the sintered body.

The apparent density of the sintered body refers to a value obtained by dividing a mass of the sintered body by a volume of the sintered body determined by the Archimedes' method, and is calculated by the following formula (2). In the following formula (2), the volume of the sintered body refers to a volume determined by the Archimedes' method.

$$Apparent density ( g / {cm}^{3} ) of sintered body = \frac{Mass ( g ) of sintered body}{Volume ( {cm}^{3} ) of sintered body} \qquad ( 2 )$$

The sintered body preferably has a thickness of 30 μm or more and 300 μm or less. When the thickness of the sintered body is 30 μm or more and 300 μm or less, the irradiated excitation light is scattered in the sintered body and efficiently wavelength converted by the fluorescent material, and the irradiated excitation light is transmitted through the sintered body, so that the sintered body emits light having: a color within the area A1; a light emission spectrum in which an integral value ratio Z2/Z1 is 0.005 or more as light including light wavelength-converted from the excitation light by the fluorescent material contained in the sintered body and the excitation light transmitted through the sintered body; and a high luminous flux. In addition, when the thickness of the sintered body is 30 μm or more and 300 μm or less, the sintered body has sufficient mechanical strength.

When the sintered body contains a nitride fluorescent material having a composition represented by the formula (I), and M² is Eu and w satisfies 0.001≤w<0.05 in the formula (I), the sintered body preferably has a thickness of 50 μm or more and 180 μm or less. When the sintered body contains a nitride fluorescent material represented by the formula (I), and M² is Eu and w satisfies 0.005≤w≤0.01 in the formula (I), the sintered body may have a thickness of 50 μm or more and 120 μm or less. When the molar ratio of the element M² as the activating element in the composition represented by the formula (I) is large, the nitride fluorescent material has a high light emission intensity upon irradiation with excitation light. In the case where the sintered body contains only a nitride fluorescent material, when the thickness of the sintered body is preferably 50 μm or more and 250 μm or less, more preferably 50 μm or more and 120 μm or less, the sintered body, upon irradiation with excitation light, emits light including light wavelength-converted from the excitation light by the fluorescent material contained in the sintered body and the excitation light transmitted through the sintered body, the light emitted from the sintered body having a color within the area A1 and an emission spectrum in which an integral value ratio Z2/Z1 is 0.005 or more.

When the sintered body contains a nitride fluorescent material having a composition represented by the formula (I), and M² is Eu and w satisfies 0.001≤w<0.01 in the formula (I), the sintered body preferably has a thickness of 50 μm or more and 250 μm or less. When the sintered body contains a nitride fluorescent material represented by the formula (I), and M² is Eu and w satisfies 0.001≤w<0.01 in the formula (I), the sintered body may have a thickness of 55 μm or more and 240 μm or less, or may have a thickness of 60 μm or more and 230 μm or less. When the molar ratio of the element M² as the activating element in the composition represented by the formula (I) is large, the nitride fluorescent material has a high light emission intensity upon irradiation with excitation light. In the case where the sintered body contains only a nitride fluorescent material, when the thickness of the sintered body is preferably 50 μm or more and 250 μm or less, the sintered body, upon irradiation with excitation light, emits light including light wavelength-converted from the excitation light by the fluorescent material contained in the sintered body and the excitation light transmitted through the sintered body, the light emitted from the sintered body having a color within the area A1 and having an emission spectrum in which an integral value ratio Z2/Z1 is 0.005 or more.

When the sintered body contains a nitride fluorescent material having a composition represented by the formula (I), and M² is Eu and w satisfies 0.001≤w<0.005 in the formula (I), the sintered body preferably has a thickness of 80 μm or more and 250 μm or less. When the sintered body contains a nitride fluorescent material represented by the formula (I), and M² is Eu and w satisfies 0.001≤w<0.005 in the formula (I), it is more preferred that the sintered body has a thickness of 90 μm or more and 240 μm or less, even more preferably 100 μm or more and 230 μm or less. When the parameter w in the product of 2 and the parameter w, which represents the molar ratio of Eu, is 0.001 or more and less than 0.005, the nitride fluorescent material has a high light emission intensity upon irradiation with excitation light. In the case where the sintered body contains only a nitride fluorescent material, when the thickness of the sintered body is preferably 80 μm or more and 250 μm or less, the sintered body, upon irradiation with excitation light, emits light having a color within the area A1 and an emission spectrum in which an integral value ratio Z2/Z1 is 0.005 or more as light including light wavelength-converted from the excitation light by the nitride fluorescent material contained in the sintered body and the excitation light transmitted through the sintered body.

When the sintered body contains a nitride fluorescent material represented by the formula (I), and M² is Eu and w satisfies 0.003≤w≤0.0045 in the formula (I), the sintered body preferably has a thickness of 100 μm or more and 200 μm or less. When the sintered body contains a nitride fluorescent material represented by the formula (I), and M² is Eu and w satisfies 0.003≤w≤0.0045 in the formula (I), it is more preferred that the sintered body has a thickness of 100 μm or more and 185 μm or less. When the element M² as the activating element in the composition represented by the formula (I) is Eu and the parameter w in the product of 2 and the parameter w, which represents the molar ratio of Eu, is 0.003 or more and less than 0.0045, the nitride fluorescent material has a high light emission intensity upon irradiation with excitation light. In the case where the sintered body contains only a nitride fluorescent material, when the thickness of the sintered body is preferably 100 μm or more and 200 μm or less, more preferably 100 μm or more and 185 μm or less, the sintered body, upon irradiation with excitation light, emits light having a color within the area A1 and having an emission spectrum in which an integral value ratio Z2/Z1 is 0.005 or more as light including light wavelength-converted from the excitation light by the nitride fluorescent material contained in the sintered body and the excitation light transmitted through the sintered body.

When the sintered body contains a nitride fluorescent material having a composition represented by the formula (I), and M² is Eu and w satisfies 0.001≤w<0.0035 in the formula (I), the sintered body preferably has a thickness of 120 μm or more and 250 μm or less. When the sintered body contains a nitride fluorescent material having a composition represented by the formula (I), and M² is Eu and w satisfies 0.001≤w<0.0035 in the formula (I), it is more preferred that the sintered body has a thickness of 130 μm or more and 240 μm or less, even more preferably 135 μm or more and 230 μm or less. When the element M² as the activating element in the composition represented by the formula (I) is Eu and the parameter w in the product of 2 and the parameter w, which represents the molar ratio of Eu, is 0.001 or more and less than 0.0035, the nitride fluorescent material may have a low light emission intensity upon irradiation with excitation light. In the case where the sintered body contains only a nitride fluorescent material, when the thickness of the sintered body is preferably 120 μm or more and 250 μm or less, more preferably 130 μm or more and 240 μm or less, and even more preferably 135 μm or more and 230 μm or less, the sintered body, upon irradiation with excitation light, emits light having a color within the area A1 and having a light emission spectrum in which an integral value ratio Z2/Z1 is 0.005 or more as light including light wavelength-converted from the excitation light by the nitride fluorescent material contained in the sintered body and the excitation light transmitted through the sintered body.

When the sintered body contains a nitride fluorescent material represented by the formula (I), and M² is Eu and w satisfies 0.002≤w≤0.003 in the formula (I), the sintered body preferably has a thickness of 130 μm or more and 183 μm or less. When the sintered body contains a nitride fluorescent material represented by the formula (I), and M² is Eu and w satisfies 0.002≤w≤0.003 in the formula (I), it is more preferred that the sintered body has a thickness of 135 μm or more and 182 μm or less. When the element M² as the activating element in the composition represented by the formula (I) is Eu and the parameter w in the product of 2 and the parameter w, which represents the molar ratio of Eu, is 0.002 or more and 0.003 or less, the nitride fluorescent material may have a low light emission intensity upon irradiation with excitation light. In the case where the sintered body contains only a nitride fluorescent material, when the thickness of the sintered body is preferably 130 μm or more and 183 μm or less, more preferably 135 μm or more and 182 μm or less, the sintered body, upon irradiation with excitation light, emits light having a color within the area A1 and having a light emission spectrum in which an integral value ratio Z2/Z1 is 0.005 or more as light including light wavelength-converted from the excitation light by the nitride fluorescent material contained in the sintered body and the excitation light transmitted through the sintered body.

When the sintered body contains a nitride fluorescent material having a composition represented by the formula (I), and M² is Eu and w satisfies 0.001≤w<0.0025 in the formula (I), the sintered body preferably has a thickness of 150 μm or more and 250 μm or less. When the sintered body contains a nitride fluorescent material represented by the formula (I), and M² is Eu and w satisfies 0.001≤w<0.0025 in the formula (I), it is more preferred that the sintered body has a thickness of 160 μm or more and 245 μm or less, even more preferably 170 μm or more and 240 μm or less. When the element M² as the activating element in the composition represented by the formula (I) is Eu and the parameter w in the product of 2 and the parameter w, which represents the molar ratio of Eu, is 0.001 or more and less than 0.0025, the nitride fluorescent material may have a low light emission intensity upon irradiation with excitation light. In the case where the sintered body contains only a nitride fluorescent material, when the thickness of the sintered body is preferably 150 μm or more and 250 μm or less, more preferably 160 μm or more and 245 μm or less, and even more preferably 170 μm or more and 240 μm or less, the sintered body, upon irradiation with excitation light, emits light: having a color within the area A1; including light wavelength-converted from the excitation light by the fluorescent material contained in the sintered body and the excitation light transmitted through the sintered body; and having an emission spectrum in which an integral value ratio Z2/Z1 is 0.005 or more.

When the sintered body contains a nitride fluorescent material having a composition represented by the formula (I), and M² is Eu and w satisfies 0.001≤w≤0.002 in the formula (I), the sintered body preferably has a thickness of 180 μm or more and 250 μm or less. When the sintered body contains a nitride fluorescent material represented by the formula (I), and M² is Eu and w satisfies 0.001≤w≤0.002 in the formula (I), it is more preferred that the sintered body has a thickness of 181 μm or more and 240 μm or less, even more preferably 182 μm or more and 230 μm or less. When the element M² as the activating element in the composition represented by the formula (I) is Eu and the parameter w in the product of 2 and the parameter w, which represents the molar ratio of Eu, is 0.001 or more and 0.002 or less, the nitride fluorescent material may have a low light emission intensity upon irradiation with excitation light. In the case where the sintered body contains only a nitride fluorescent material, when the thickness of the sintered body is preferably 180 μm or more and 250 μm or less, more preferably 181 μm or more and 240 μm or less, and even more preferably 182 μm or more and 230 μm or less, the sintered body, upon irradiation with excitation light, emits light: having a color within the area A1; including light wavelength-converted from the excitation light by the fluorescent material contained in the sintered body and the excitation light transmitted through the sintered body; and having a light emission spectrum in which an integral value ratio Z2/Z1 is 0.005 or more.

The sintered body is preferably formed by calcining fluorescent material particles having an average particle diameter Db (Fisher Sub-Sieve Sizer's number) of less than 1 μm as measured by a Fisher Sub-Sieve Sizer method (hereinafter also referred to as “FSSS method”). When the sintered body is formed by calcining fluorescent material particles having an average particle diameter Db of less than 1 μm as measured by the FSSS method, the particle growth of the fluorescent material particles is easily facilitated, and the grain size of the fluorescent material particles, which can be observed on the fractured surface of the sintered body, is larger than that of the raw material of the fluorescent material particles. As a result, the interface within the sintered body formed from the fluorescent material particles is reduced, which allows light to transmit easily through the sintered body. In the fluorescent material particles used as the raw material for forming the sintered body, the average particle diameter Db, as measured by the FSSS method, is preferably 0.01 μm or more and 0.99 μm or less, more preferably 0.05 μm or more and 0.98 μm or less, even more preferably 0.10 μm or more and 0.95 μm or less, and may be 0.50 μm or more and 0.95 μm or less. The FSSS method is a type of air permeability method and is a method of measuring a specific surface area by utilizing the flow resistance of air to mainly determine a particle diameter of primary particles.

The sintered body is preferably formed by calcining fluorescent material particles having a particle diameter ratio Db/Dm of an average particle diameter Db, as measured by the Fisher Sub-Sieve Sizer method, to a volume median diameter Dm, as measured by a laser diffraction particle size distribution measurement method, of 0.45 or less. The laser diffraction particle size distribution measurement method is a method of measuring particle size distribution by utilizing scattered laser light irradiated on particles without distinguishing between primary and secondary particles. The volume median diameter Dm is a volume median diameter where the cumulative frequency from the small diameter side is 50% in the particle size distribution measured by the laser diffraction particle size distribution measurement method. The closer the particle diameter ratio Db/Dm is to 1, the smaller the amount of secondary particles contained, resulting in a large proportion of primary particles contained in the powder. When the particle diameter ratio Db/Dm of the fluorescent material is 0.45 or less, the proportion of secondary particles contained in the powder increases. When the sintered body is formed by calcining fluorescent material particles having a particle diameter ratio Db/Dm of 0.45 or less, the proportion of secondary particles contained in the powder containing the raw material of the fluorescent material particles is large, and small particles can be interposed between large particles, which facilitates increase in the molding density. As a result, the particle growth of the fluorescent material particles is easily facilitated, resulting in a sintered body with a high relative density. In the fluorescent material particles used as the raw material for forming the sintered body, the particle diameter ratio Db/Dm may be 0.44 or less, may be 0.43 or less, or may be 0.42 or less; and is preferably 0.30 or more, may be 0.32 or more, or may be 0.35 or more.

The sintered body is preferably formed by calcining fluorescent material particles having a volume median diameter Dm, as measured by the laser diffraction particle size distribution measurement method, of 0.02 μm or more and 3.5 μm or less, and the range may be 0.05 μm or more and 3.2 μm or less, or may be 0.05 μm or more and 3.0 μm or less. When forming the sintered body by calcining fluorescent material particles having a volume median diameter, as measured by the laser diffraction particle size distribution measurement method, of 0.02 μm or more and 3.5 μm or less, the particle growth of the fluorescent material particles is easily facilitated, so that the grain size of the fluorescent material particles, which can be observed on the fractured surface of the sintered body, is larger than that of the raw material of the fluorescent material particles. This reduces the interface within the sintered body formed from the fluorescent material particles, allowing light to transmit easily through the sintered body. When the volume median diameter Dm of the fluorescent material particles used as the raw material for forming the sintered body is 0.02 μm or more and 3.5 μm or less, the particle diameter ratio Db/Dm becomes 0.45 or less, and the grain size of the fluorescent material particles, which can be observed on the fractured surface of the sintered body, becomes large, so that the interface of the fluorescent material particles can be reduced to obtain a sintered body having a high relative density.

In a scanning electron microscope (SEM) image of a fractured surface of the sintered body, it is preferred that the individual fluorescent material particles constituting the sintered body can be observed, and the long diameter of the fluorescent material particles is 0.1 μm or more and 20 μm or less. When the long diameter of the fluorescent material particles that can be observed on the fractured surface of the sintered body in the SEM image is 0.1 μm or more and 20 μm or less, the fluorescent material particles are larger than the raw material of the fluorescent material particles, and it can be assumed that the particle growth of the raw material of the fluorescent material particles is facilitated. The long diameter of each fluorescent material particle refers to the longest diameter measured from one end of the outline of the fluorescent material particle where the outline can be observed on the fractured surface of the sintered body in the SEM image to the other end of the fluorescent material particle through the inside of the fluorescent material particle. The sintered body may have fluorescent material particles having a long diameter, which can be observed on the fractured surface of the sintered body in the SEM image, of 0.15 μm or more and 15 μm or less.

The method for producing a sintered body preferably includes providing a fluorescent material, providing a molded body containing the fluorescent material, and obtaining a sintered body by calcining the molded body.

For the fluorescent material, a fluorescent material being at least one selected from the group consisting of a nitride fluorescent material represented by the formula (I) and an α-SiAlON fluorescent material having a composition represented by the formula (II) is provided. The fluorescent material may be provided by being supplied from another company, or by producing using the following method.

When the fluorescent material includes a nitride fluorescent material represented by the formula (I), the nitride fluorescent material is preferably prepared by mixing a first compound containing Ba, a second compound containing an element M¹ being at least one selected from the group consisting of Sr, Ca, and Mg, a third compound containing an element M² being at least one selected from the group consisting of Eu, Ce, Tb, and Mn, and a compound containing Si, to obtain a raw material mixture such that Ba, the element M¹, the element M², and Si satisfy the composition represented by the formula (I), and by subjecting the raw material mixture to heat treatment at a temperature of 980° C. or higher and 1,680° C. or lower in an atmosphere containing nitrogen. The nitride fluorescent material may be produced with reference to Japanese Unexamined Patent Publication No. 2020-083739. The nitride fluorescent material is preferably composed of fluorescent material particles having an average particle diameter Db, as measured by the FSSS method, of less than 1 μm. The nitride fluorescent material is preferably composed of fluorescent material particles having a particle diameter ratio Db/Dm of an average particle diameter Db, as measured by the FSSS method, to a volume median diameter Dm, as measured by the laser diffraction particle size distribution measurement method, of 0.45 or less.

In providing a molded body, the raw material for forming a molded body includes a nitride fluorescent material represented by the formula (I) and an α-SiAlON fluorescent material having a composition represented by the formula (II). In providing a molded body, the raw material for forming a molded body is preferably composed of a fluorescent material selected from the group consisting of a nitride fluorescent material represented by the formula (I) and an α-SiAlON fluorescent material represented by the formula (II). In providing a molded body, the raw material for forming a molded body is preferably composed of a nitride fluorescent material having a composition represented by the formula (I). The content of the nitride fluorescent material having a composition represented by the formula (I) in the raw material for forming a molded body is preferably 100% by mass, may be 95% by mass or more, may be 97% by mass or more, may be 98% by mass or more, may be 99% by mass or more, or may be 99.5% by mass or more. The remaining content of the nitride fluorescent material having a composition represented by the formula (I) in the raw material for forming a molded body may be an α-SiAlON fluorescent material having a composition represented by the formula (II). It is preferred that the raw material for forming a molded body or the raw material mixture does not contain impurities that inhibit the particle growth of the raw fluorescent material particles, except for the nitride fluorescent material represented by the formula (I) and the α-SiAlON fluorescent material represented by the formula (II). The impurities that inhibit the particle growth of the fluorescent material particles here refer to hydrides, nitrides, carbonates, chlorides, imide compounds, and amide compounds that contain elements contained in the nitride fluorescent material or the α-SiAlON fluorescent material.

In providing a molded body, the raw material containing a fluorescent material being at least one selected from the group consisting of a nitride fluorescent material and an α-SiAlON fluorescent material is molded into a desired shape to obtain a molded body. The raw material containing a fluorescent material being at least one selected from the group consisting of a nitride fluorescent material and an α-SiAlON fluorescent material is preferably in the form of a powder, or may be in the form of a slurry containing a powder. As the technique of molding the molded body, a press molding technique in which a powder is molded by pressing, or a slurry molding technique in which a slurry containing a powder is prepared, and a molded body is obtained from the slurry. Examples of the press molding method include a die press molding method and a cold isostatic pressing (CIP) specified in No. 2109 of JIS Z2500: 2000. To adjust the shape of the molded body, two kinds of molding techniques may be employed, and CIP molding may be performed after die press molding. In CIP molding, the molded body is preferably pressed using water as a medium.

The pressure in die press molding is preferably 1 MPa or more and 50 MPa or less, more preferably 2 MPa or more and 20 MPa or less, and even more preferably 2 MPa or more and 15 MPa or less. When the pressure in die press molding is in the above range, the molded body can be formed into a desired shape.

The pressure in CIP molding is preferably 50 MPa or more and 500 MPa or less, more preferably 100 MPa or more and 450 MPa or less, and even more preferably 200 MPa or more and 400 MPa or less. When the pressure in CIP molding is in the above range, the density (molding density) of the molded body can be increased to obtain a molded body having a substantially uniform density throughout, and the density of the resulting sintered body can be increased in the subsequent calcination step.

In obtaining a sintered body by calcining the molded body, the temperature of the calcination is preferably 1,600° C. or higher and 2,200° C. or lower, more preferably 1,600° C. or higher and 2,000° C. or lower, even more preferably 1,600° C. or higher and 1,900° C. or lower, and still more preferably 1,600° C. or higher and 1,800° C. or lower. When the temperature of the calcination is 1,600° C. or higher and 2,200° C. or lower, a sintered body having a relative density of 97% or more can be obtained. In the present specification, the term calcination refers to the calcination of an uncalcined molded body.

Examples of the calcination method include an atmosphere sintering method in which the calcination is performed in a non-oxidizing atmosphere without applying pressure or load, an atmosphere pressure sintering method in which the calcination is performed under pressure in a non-oxidizing atmosphere, a hot press sintering method, and a spark plasma sintering (SPS) method.

The calcination is preferably performed in an atmosphere containing a nitrogen gas. The atmosphere containing a nitrogen gas is preferably an atmosphere containing at least 99% by volume or more of nitrogen. The nitrogen content in the atmosphere containing a nitrogen gas is preferably 99% by volume or more, more preferably 99.5% by volume or more. The atmosphere containing a nitrogen gas may contain, in addition to nitrogen, a trace amount of gas such as oxygen, and the content of oxygen in the atmosphere containing a nitrogen gas is preferably 1% by volume or less, more preferably 0.5% by volume or less, even more preferably 0.1% by volume or less, still more preferably 0.01% by volume or less, and particularly preferably 0.001% by volume or less. The atmosphere in the calcination step may be a reducing atmosphere containing nitrogen, or may be an atmosphere containing nitrogen and a hydrogen gas. When a hydrogen gas is contained in the atmosphere containing nitrogen in the calcination step, the content of the hydrogen gas in the atmosphere is preferably 1% by volume or more, more preferably 5% by volume or more, and even more preferably 10% by volume or more. The atmosphere for the heat treatment may be a reducing atmosphere using a solid carbon in an air atmosphere.

In obtaining a sintered body, calcining the molded body in an atmosphere containing a nitrogen gas allows for obtaining a sintered body having a relative density of 97% or more and a grain having a composition of a nitride fluorescent material having a high light emission intensity. In this case, when the element M², which is an activating agent for the nitride fluorescent material, is Eu, the ratio of divalent Eu²⁺, which is an activating agent, contributing to light emission in the nitride fluorescent material or α-SiAlON fluorescent material increases, so that a sintered body having a high light emission intensity can be obtained. Divalent Eu²⁺ is easily oxidized to trivalent Eu³⁺. However, by calcining the molded body in a highly reducing atmosphere containing a nitrogen gas, trivalent Eu³⁺ in the nitride fluorescent material contained in the molded body is reduced to divalent Eu²⁺, and the ratio of divalent Eu²⁺ in the nitride fluorescent material or α-SiAlON fluorescent material increases, so that a sintered body containing crystals having a composition of a nitride fluorescent material or α-SiAlON fluorescent material having a high light emission intensity can be obtained.

The atmospheric pressure in the calcination is preferably 0.1 MPa or more and 2.0 MPa or less, more preferably 0.2 MPa or more and 1.5 MPa or less, and even more preferably 0.5 MPa or more and 1.2 MPa or less. The atmospheric pressure in the calcination is preferably a gauge pressure. When the atmospheric pressure in the calcination is in the above range, the decomposition of the crystal structure is inhibited, and a sintered body containing a fluorescent material being at least one selected from the group consisting of a nitride fluorescent material and an α-SiAlON fluorescent material having a high light emission intensity can be obtained.

The duration of the calcination may be appropriately selected depending on the atmospheric pressure. The duration of the calcination is, for example, 0.5 hour or more and 20 hours or less, preferably 1 hour or more and 10 hours or less.

The method for producing a sintered body may include processing a sintered body after obtaining the sintered body. In the method for producing a sintered body, processing a sintered body includes cutting the resulting sintered body into a desired size. Examples of the cutting technique include known techniques such as techniques using wire saws. The resulting sintered body may be processed to have a thickness of 30 μm or more and 300 μm or less so as to emit, upon irradiation with excitation light, light having a color within the area A1 and having a light emission spectrum in which the integral value ratio Z2/Z1 is 0.005 or more as light including the light emitted from the sintered body and the excitation light transmitted through the sintered body.

The sintered body may be combined with a light emitting element such as an LED or LD to form a light emitting device. In the light emitting device, the sintered body is positioned at a location to be irradiated with light emitted from an excitation light source such as a light emitting element, light irradiated from the excitation light source is wavelength-converted by the sintered body, and light having a color within the area A1 is emitted.

The light emitting device includes an excitation light source that emits light having a light emission peak wavelength of 380 nm or more and 570 nm or less, and the sintered body that is positioned at a location to be irradiated with light emitted from the excitation light source. In the light emitting device, the sintered body may be used in combination with another sintered body containing another fluorescent material having a composition different from that of a fluorescent material selected from the group consisting of a nitride fluorescent material and an α-SiAlON fluorescent material.

The excitation light source that emits light having a light emission peak wavelength of 380 nm or more and 570 nm or less is preferably a light emitting element. The light emitting element preferably has a light emission peak wavelength of 400 nm or more and 550 nm or less. For example, the light emitting element is preferably a semiconductor light emitting element using a nitride-based semiconductor (In_{X}Al_{Y}Ga_{1-X-Y}N, 0≤X, 0≤Y, X+Y≤1). The use of a semiconductor light emitting element as the excitation light source allows for obtaining a stable light emitting device having high efficiency, high output linearity with respect to the input, and high resistance to mechanical impact.

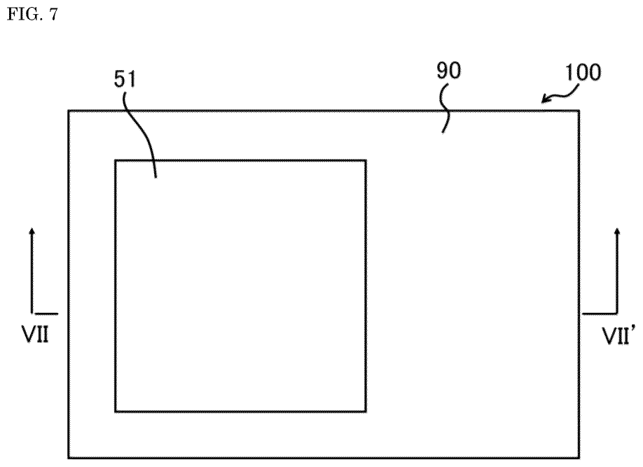

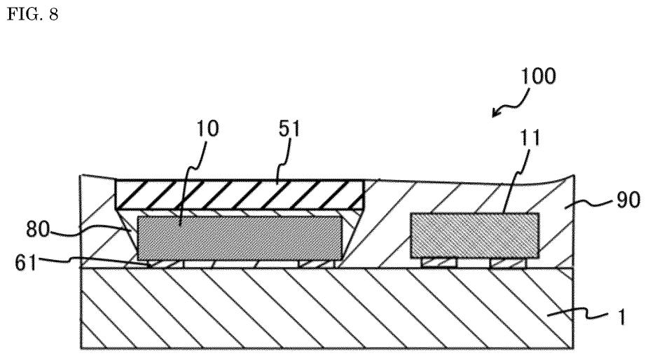

FIGS. 7 and 8 show a configuration of an exemplary light emitting device using the sintered body as a wavelength conversion member. FIG. 7 is a schematic plan view of a light emitting device 100. FIG. 8 is a schematic cross-sectional view of the VII-VII′ line of the light emitting device 100 shown in FIG. 7. The light emitting device 100 includes a light emitting element 10 having a light emission peak wavelength of 380 nm or more and 570 nm or less, and a wavelength conversion member 51 that emits light upon excitation with light emitted from the light emitting element 10. The light emitting element 10 is flip-chip mounted on a substrate 1 via a conductive member 61 such as a bump. The wavelength conversion member 51 is disposed on a light emitting surface of the light emitting element 10 via an adhesive layer 80. Lateral surfaces of the light emitting element 10 and lateral surfaces of the wavelength conversion member 51 are covered with a covering member 90 that reflects light. The light emitting element 10 receives electric power from the outside of the light emitting device 100 via a wiring and the conductive member 61 formed on the substrate 1, thereby allowing the light emitting device 100 to emit light. The light emitting device 100 may include a semiconductor element 11, such as a protective element, for preventing the light emitting element 10 from being destroyed due to excessive voltage application. The semiconductor element 11 may be mounted on the substrate 1 via the conductive member 61. The covering member 90 is disposed to cover, for example, the semiconductor element 11. The following describes the members used in the light emitting device. For the details, for example, the disclosure of Japanese Unexamined Patent Publication No. 2014-112635 may be referenced.

The adhesive layer is preferably made of a material that can optically connect the light emitting element and the wavelength conversion member. For example, the material constituting the adhesive layer is preferably at least one resin selected from the group consisting of an epoxy resin, a silicone resin, a phenol resin, and a polyimide resin, or an inorganic material such as silicon oxide or silicon nitride. The light emitting element and the wavelength conversion member may be directly bonded without an adhesive layer.

Examples of the semiconductor element optionally disposed in the light emitting device include a transistor for controlling the light emitting element and a protective element for inhibiting the destruction and the performance deterioration of the light emitting element due to excessive voltage application. Examples of the protective element include a Zener diode. When the light emitting device includes a covering member, it is preferable to use an insulating material as the material of the covering member. More specific examples thereof include a phenol resin, an epoxy resin, a bismaleimide triazine resin (BT resin), a polyphthalamide (PPA) resin, and a silicone resin. A colorant, a fluorescent material, and a filler may be optionally added to the covering member. The light emitting device may use a bump as the conductive member. Examples of the material of the bump include Au and an alloy thereof, and examples of the other conductive member include eutectic solder (Au—Sn), Pb—Sn, and lead-free solder.

The following describes an example of the method for producing a light emitting device. For the details, for example, the disclosure of Japanese Unexamined Patent Publication No. 2014-112635 or Japanese Unexamined Patent Publication No. 2017-117912 may be referenced. The method for producing a light emitting device preferably includes a step of disposing a light emitting element, optionally a step of disposing a semiconductor element, a step of providing a wavelength conversion member, a step of bonding a light emitting element and a wavelength conversion member, and a step of disposing a covering member.

For example, in the step of disposing a light emitting element, a light emitting element is disposed on a substrate. The light emitting element and a semiconductor element are flip-chip mounted, for example, on the substrate. In the step of providing a wavelength conversion member, a wavelength conversion member composed of a sintered body obtained by the above production method is providing. Next, in the step of bonding a light emitting element and a wavelength conversion member, the provided wavelength conversion member is arranged to face the light emitting surface of the light emitting element, and the wavelength conversion member is bonded to the light emitting element by an adhesive layer. Next, in the step of disposing a covering member, the lateral surfaces of the light emitting element and the wavelength conversion member are covered with a covering member. The covering member is for reflecting light emitted from the light emitting element, and when the light emitting device also includes a semiconductor element, the covering member is preferably disposed so as to embed the semiconductor element. Thus, the light emitting device shown in FIGS. 7 and 8 can be produced.

### EXAMPLES

The present disclosure is hereunder specifically described with reference to the following Examples. The present disclosure is not limited to the following Examples.

### Providing Nitride Fluorescent Materials 1 to 6

Compounds of BasN₂, Sr₃N₂, EuN, and SisN₄ were used as raw materials. The compounds as raw materials were weighed in a glove box with an inert gas atmosphere such that the molar ratio of each element in terms of charge composition was as shown in Table 1, and the compounds were mixed to obtain a raw material mixture. The resulting raw material mixture was filled into a crucible, and subjected to heat treatment at a gas pressure of 0.9 MPa in terms of gauge pressure and a temperature of 1,600° C. for 5 hours in an atmosphere containing 99.9% by volume or more of nitrogen, the remainder being oxygen (0.1% by volume or less), to obtain a calcined product. Because the particles were sintered together in the resulting calcined product, the particles were dispersed, and then subjected to sieve classification to remove coarse and fine particles to obtain nitride fluorescent materials 1 to 6 having the target compositions shown in Table 1. The compositions of the resulting nitride fluorescent material particles each have the composition represented by formula (I), and are almost the same as the charge composition.

The resulting nitride fluorescent materials were subjected to the following evaluations. The results are shown in Table 5.

### Average Particle Diameter Db

For the nitride fluorescent materials 1 to 6, the average particle diameter Db was measured by the FSSS method using a Fisher Sub-Sieve Sizer Model 95 (manufactured by Fisher Scientific Inc.).

### Volume Median Diameter Dm

For the nitride fluorescent materials 1 to 6, the volume median diameter Dm, where the cumulative volume frequency from the small diameter side reaches 50%, was measured using a laser diffraction particle size distribution measurement apparatus (Mastersizer 2000, manufactured by Malvern Panalytical Ltd.). Chromaticity Coordinates (x, y), Relative Luminance (%), Light Emission Peak Wavelength, and Full Width at Half Maximum

Using a fluorospectrophotometer (QE-2000, manufactured by Otsuka Electronics Co., Ltd.), each of the nitride fluorescent materials 1 to 6 was irradiated with excitation light having a light emission peak wavelength of 450 nm and an output of 1,300 mW/mm² or more and 6,000 mW/mm² or less, specifically 1,300 mW/mm² or more and 1,500 mW/mm² or less, and the light emission spectrum of the light emitted from each nitride fluorescent material was measured at room temperature. The chromaticity coordinates (x, y) in the chromaticity diagram of the CIE 1931 color system were determined from the light emission spectrum data measured for each nitride fluorescent material. From the light emission spectrum data of the light emitted from each nitride fluorescent material measured for each nitride fluorescent material, the luminance of each of the nitride fluorescent materials 1 to 4 and 6 was determined as a relative luminance relative to the luminance of the nitride fluorescent material 5, which has the lowest molar ratio of the activating element Eu, being 100%. The light emission peak wavelength λp (nm) and the full width at half maximum were determined from the light emission spectrum data of the light emitted from each nitride fluorescent material measured for each nitride fluorescent material. In the present specification, the full width at half maximum refers to a width of a wavelength at 50% intensity of the light emission intensity at the light emission peak wavelength, at which the maximum light emission intensity is exhibited, in the light emission spectrum.

### True Density

For the nitride fluorescent materials 1 to 6, the true density (g/cm³) was determined from the composition of each nitride fluorescent material.

TABLE 5

| | | | | | | | | | | | Light | | |
|---|---|---|---|---|---|---|---|---|---|---|---|---|---|
| | | | | | | | | | | | emission | | |
| | | | | | Average | Volume | | | | | peak | Full | |
| | | | | | particle | median | Particle | | | | wave- | width | |
| | | Charge composition | | | diameter | diameter | diameter | Chromaticity | | Relative | length | at half | True |
| | | | Sr | Eu | Db | Dm | ratio | coordinates | | luminance | [symbol] p | maximum | density |
| | Composition | Ba | u × 2 | w × 2 | (μm) | (μm) | Db/Dm | x | y | (%) | (nm) | (nm) | (g/cm³) |
| Nitride | (Ba [symbol] Sr [symbol] Eu [symbol] ) [symbol] N [symbol] | 1.270 | 0.720 | 0.010 | 0.85 | 2.41 | 0.35 | 0.541 | 0.454 | 192 | 595 | 89.0 | 4.36 |
| fluorescent | | | | | | | | | | | | | |
| material 1 | | | | | | | | | | | | | |
| Nitride | (Ba [symbol] Sr [symbol] Eu [symbol] ) [symbol] N [symbol] | 1.270 | 0.725 | 0.005 | 0.80 | 2.06 | 0.39 | 0.525 | 0.468 | 154 | 590 | 91.8 | 4.36 |
| fluorescent | | | | | | | | | | | | | |
| material 2 | | | | | | | | | | | | | |
| Nitride | (Ba [symbol] Sr [symbol] Eu [symbol] ) [symbol] N [symbol] | 1.120 | 0.873 | 0.007 | 0.95 | 2.31 | 0.41 | 0.553 | 0.445 | 149 | 595 | 84.4 | 4.33 |
| fluorescent | | | | | | | | | | | | | |
| material 3 | | | | | | | | | | | | | |
| Nitride | (Ba [symbol] Sr [symbol] Eu [symbol] ) [symbol] N [symbol] | 1.120 | 0.875 | 0.005 | 0.90 | 2.21 | 0.41 | 0.548 | 0.450 | 127 | 595 | 82.8 | 4.33 |
| fluorescent | | | | | | | | | | | | | |
| material 4 | | | | | | | | | | | | | |
| Nitride | (Ba [symbol] Sr [symbol] Eu [symbol] ) [symbol] N [symbol] | 1.120 | 0.877 | 0.003 | 0.85 | 2.23 | 0.38 | 0.542 | 0.456 | 100 | 590 | 82.4 | 4.33 |
| fluorescent | | | | | | | | | | | | | |
| material 5 | | | | | | | | | | | | | |
| Nitride | (Ba [symbol] Sr [symbol] Eu [symbol] ) [symbol] N [symbol] | 1.400 | 0.593 | 0.007 | 0.70 | 2.37 | 0.30 | 0.539 | 0.459 | 155 | 584 | 80.2 | 4.33 |
| fluorescent | | | | | | | | | | | | | |
| material 6 | | | | | | | | | | | | | |

[symbol]

indicates data missing or illegible when filed

The nitride fluorescent materials 1 to 6 all had a composition represented by the formula (I). The nitride fluorescent materials 1 to 6 all had an average particle diameter Db, as measured by the FSSS method, of less than 1 μm, specifically 0.70 μm or more and 0.95 μm or less. The nitride fluorescent materials 1 to 6 all had a particle diameter ratio Db/Dm of 0.45 or less, specifically 0.30 or more and 0.41 or less.

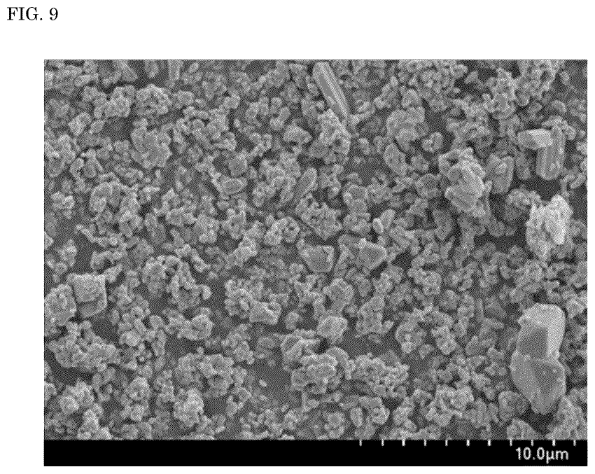

FIG. 9 is an SEM micrograph of the nitride fluorescent material 5 observed with a scanning electron microscope (SEM). The nitride fluorescent material 5 contained many fluorescent material particles having a particle diameter of less than 1 μm.

The sintered bodies according to Examples and Comparative Examples described below were subjected to the following measurements. The results are shown in Tables 6 to 11.

### Relative Density (%)

The relative density of the sintered body according to each of Examples and Comparative Examples was calculated by the calculation formulas (1) and (2). For the true density of the sintered body, the true density of the nitride fluorescent material as the raw material of the sintered body according to each of Examples and Comparative Examples was used for the calculation.

### Chromaticity Coordinates (x, y)

The sintered body according to each of Examples and Comparative Examples was mounted on a light emitting element (LED) and positioned at a location to be irradiated with light emitted from the light emitting element to produce a light emitting device for testing. The sintered body was irradiated with excitation light having a light emission peak wavelength of 450 nm and an output of 1,300 mW/mm² or more and 6,000 mW/mm² or less, specifically 1,300 mW/mm² or more and 1,500 mW/mm² or less, by applying a current of 1 A to the light emitting element; the emission spectrum of the light emitted from each light emitting device for testing, the light including light wavelength-converted from the excitation light by the fluorescent material contained in the sintered body and the excitation light transmitted through the sintered body, was measured using a multichannel spectrometer (PMA-12, manufactured by Hamamatsu Photonics K.K.); and the chromaticity coordinates (x, y) in the chromaticity diagram of the CIE 1931 color system were determined from the measured light emission spectrum. In the measured light emission spectrum of the light emitted from each sintered body, the integral value of the light emission intensities in the wavelength width range surrounded by the horizontal axis where the light emission intensity (a.u. (arbitrary unit)) is 0 (zero) and by the light emission spectrum in the wavelength range of more than 500 nm and 800 nm or less was measured as the first integral value Z1. In the measured light emission spectrum of the light emitted from each sintered body, the integral value of the light emission intensities in the wavelength width range surrounded by the horizontal axis where the light emission intensity (a.u. (arbitrary unit)) is 0 (zero) and by the light emission spectrum in the wavelength range of 400 nm or more and 500 nm or less was measured as the second integral value Z2. The integral value ratio Z2/Z1 of the second integral value Z2 to the first integral value Z1 was determined. The chromaticity coordinates of the light emitting devices for testing were plotted on the chromaticity diagram of the CIE 1931 color system, and it was confirmed whether they were within or outside the ranges of areas A1, A2, and A3. Light emitting devices for testing emitting light having a color within the area in each range were described as “IN”, and those emitting light having a color outside of the area in each range were described as “OUT”.

### Relative Luminous Flux (%)

In the light emitting device for testing according to each of Examples and Comparative Examples, the sintered body was irradiated with excitation light having a light emission peak wavelength of 450 nm and an output of 1,300 mW/mm² or more and 6,000 mW/mm² or less, specifically 1,300 mW/mm² or more and 1,500 mW/mm² or less, by applying a current of 1 A to the light emitting element, and the luminous flux (lm) of the light emission of each light emitting device was measured using a total luminous flux measuring apparatus. The luminous flux of the light emission of each light emitting device was determined as a relative luminous flux (%) relative to the lowest luminous flux in Examples using the same nitride fluorescent material being 100%.

### Examples 1-1 to 1-3

The nitride fluorescent material 1 was filled into a mold, and press-molded at a pressure of 2 MPa to form a cylindrical molded body having a diameter of 28.5 mm and a thickness of 10 mm. The molded body was further subjected to CIP molding at a pressure of 352.8 MPa to form a cylindrical molded body having a diameter of 25 mm and a thickness of 9 mm. The resulting molded body was composed only of the above-mentioned nitride fluorescent material, which was 100% by mass of the nitride fluorescent material.

### Obtaining Sintered Body

The resulting molded body was placed in a calcining furnace (manufactured by Fujidempa Kogyo Co., Ltd.) and calcined at 1,675° C. and 0.9 MPa with a holding time of 1 hour in an atmosphere containing 99.9% by volume or more of nitrogen, the remainder being oxygen (0.1% by volume or less), to obtain a sintered body.

### Light Emitting Device for Testing

The resulting sintered body was processed to have each of the thicknesses shown in Table 6 to obtain a sintered body according to each of Examples 1-1 to 1-3. Each sintered body was disposed at a location to be irradiated with light emitted from a light emitting element (LED) configured to emit excitation light having a light emission peak wavelength of 450 nm and an output of 1,300 mW/mm² or more and 6,000 mW/mm² or less, specifically 1,300 mW/mm² or more and 1,500 mW/mm² or less, to obtain a light emitting device for testing. The light emitting device according to each of Examples 1-1 to 1-3 was subjected to the above measurements. The results are shown in Table 6.

TABLE 6

| | | | Light emitting device | | | | | | | | |
|---|---|---|---|---|---|---|---|---|---|---|---|
| | | | | | Integral | Integral | | | | | |
| | Sintered body | | | | value | value | Integral | Relative | | | |
| | | Relative | Chromaticity | | 500 nm- | 400 nm- | value | luminous | | | |
| Nitride fluorescent material 1 | Thickness | density | coordinates | | 800 nm | 500 nm | ratio | flux | Area | Area | Area |
| (Ba [symbol] Sr [symbol] Eu [symbol] ) [symbol] Si [symbol] N [symbol] | (μm) | (%) | x | y | Z1 | Z2 | Z2/Z1 | (%) | A1 | A2 | A3 |
| Example 1-1 | 60 | 97.6 | 0.5690 | 0.4119 | 117.577 | 1.496 | 0.0127 | 10 [symbol] .4 | IN | IN | OUT |
| Example 1-2 | 70 | 97.3 | 0.5737 | 0.4129 | 116.494 | 0.9 [symbol] 4 | 0.0085 | 101 | IN | IN | IN |
| Example 1-3 | [symbol] 9 | 99.3 | 0.5810 | 0.4106 | 115.724 | 0.588 | 0.0051 | 100 | IN | IN | OUT |

[symbol]

indicates data missing or illegible when filed

When the light emitting devices using the sintered bodies according to Examples 1-1 to 1-3 were irradiated with excitation light, light including light wavelength converted from the excitation light by the fluorescent material contained in the sintered body and the excitation light transmitted through the sintered body was emitted from the sintered body of each of the light emitting devices, and the light emitted from the sintered body had a color within the area A1 and had an emission spectrum in which an integral value ratio Z2/Z1 was 0.005 or more. In these light emitting devices, the excitation light having a wavelength shorter than that of the light wavelength converted by the fluorescent material contained in the sintered body was transmitted through the sintered body. The light emitting device according to each of Examples 1-1 to 1-3 emitted light having an amber color on the short wavelength side of the area A1 and having a high relative luminous flux.

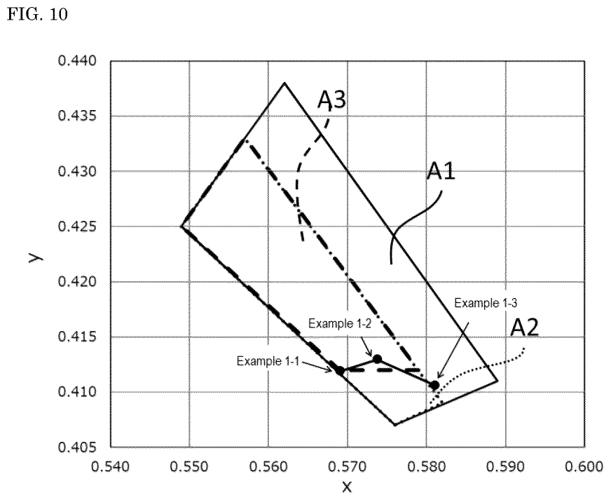

FIG. 10 is a chromaticity diagram of the CIE1931 color system showing the areas A1, A2, and A3, as well as the chromaticity coordinates (x, y) of the light emission of the light emitting device using the sintered body according to each of Examples 1-1 to 1-3. As shown in FIG. 10, the light emitting device using the sintered body according to each of Examples 1-1 to 1-3 emitted light having an amber color within the area A2 on the shorter wavelength side of the area A1.

The sintered body used in the light emitting device according to each of Examples 1-1 to 1-3 contained the nitride fluorescent material having the composition represented by the formula (I), wherein in the formula (I), M² was Eu, w satisfied 0.001≤w<0.05, more specifically 0.005≤w≤0.01, and the molar ratio of Eu as the activating element was large, so that the light emission intensity upon irradiation with excitation light was high, and the sintered body was thin with a thickness of 50 μm or more and 120 μm or less. The light emitting device according to each of Examples 1-1 to 1-3, even when a thin sintered body was used, emitted light having a color within the area A1 and having an emission spectrum in which an integral value ratio Z2/Z1 is 0.005 or more as light emitted from the sintered body including light wavelength-converted from the excitation light by the fluorescent material contained in the sintered body and the excitation light transmitted through the sintered body.

### Examples 2-1 to 2-5 and Comparative Example 2-6

A sintered body was obtained in the same or similar manner as in Examples 1-1 to 1-3, except that the nitride fluorescent material 2 was used, and the resulting sintered body was processed to have each of the thicknesses shown in Table 7 to obtain a sintered body according to each of Examples 2-1 to 2-5 and Comparative Example 2-6. Each sintered body was disposed at a location to be irradiated with light emitted from a light emitting element (LED) configured to emit excitation light having a light emission peak wavelength of 450 nm and an output of 1,300 mW/mm² or more and 6,000 mW/mm² or less, specifically 1,300 mW/mm² or more and 1,500 mW/mm² or less, to produce a light emitting device for testing. The light emitting device according to each of Examples 2-1 to 2-5 and Comparative Example 2-6 was subjected to the above measurements. The results are shown in Table 7.

TABLE 7

| | | | Light emitting device | | | | | | | | |
|---|---|---|---|---|---|---|---|---|---|---|---|
| | | | | | Integral | Integral | | | | | |
| | Sintered body | | | | value | value | Integral | Relative | | | |
| | | Relative | Chromaticity | | 500 nm- | 400 nm- | value | luminous | | | |
| Nitride fluorescent material 2 | Thickness | density | coordinates | | 800 nm | 500 nm | ratio | flux | Area | Area | Area |
| (Ba [symbol] Sr [symbol] Eu [symbol] ) [symbol] Si [symbol] N [symbol] | (μm) | (%) | x | y | Z1 | Z2 | Z2/Z1 | (%) | A1 | A2 | A3 |
| Example 2-1 | 135 | 99.2 | 0.5534 | 0.424 [symbol] | 116.4 [symbol] 3 | 1. [symbol] 32 | 0.0157 | 111.3 | IN | IN | IN |
| Example 2-2 | 141 | 98.9 | 0.5555 | 0.4250 | 11 [symbol] .27 [symbol] | 1. [symbol] 10 | 0.013 [symbol] | 10 [symbol] .7 | IN | IN | IN |
| Example 2-3 | 155 | 98.8 | 0.5593 | 0.4254 | 115. [symbol] 2 | 1.1 [symbol] 0 | 0.0102 | 104.0 | IN | IN | IN |
| Example 2-4 | 1 [symbol] | 98.8 | 0.5619 | 0.4253 | 115.17 [symbol] | 0.9 [symbol] 9 | 0.00 [symbol] 4 | 101. [symbol] | IN | IN | IN |
| Example 2-5 | 1 [symbol] 2 | 98.9 | 0.5 [symbol] 7 [symbol] | 0.4233 | 114.468 | 0. [symbol] 40 | 0.005 [symbol] | 100.0 | IN | IN | IN |
| Comparative Example 2-6 | 1 [symbol] 1 | 98.1 | 0.5707 | 0.4215 | 113. [symbol] 31 | 0.502 | 0.0044 | 9 [symbol] .0 | IN | OUT | OUT |

[symbol]

indicates data missing or illegible when filed

When the light emitting devices using the sintered bodies according to Examples 2-1 to 2-5 are irradiated with excitation light, light including light wavelength-converted from the excitation light by the fluorescent material contained in the sintered body and the excitation light transmitted through the sintered body is emitted from the sintered body of each of the light emitting devices, and the light emitted from the sintered body had a color within the area A1 and had a light emission spectrum in which an integral value ratio Z2/Z1 was 0.005 or more. In these light emitting devices, the excitation light having a wavelength shorter than that of the light wavelength-converted by the sintered body was transmitted through the sintered body. The light emitting device according to each of Examples 2-1 to 2-5 emitted light having an amber color on the short wavelength side of the area A1 and having a high relative luminous flux.

The light emitting devices using the sintered bodies according to Comparative Example 2-6 emitted light having a color within the area A1 upon irradiation with excitation light. However, the integral value ratio Z2/Z1 of the light emitted from each of these light emitting devices was less than 0.005 in the light emission spectrum of the light emitted from the sintered body including light wavelength-converted from the excitation light by the fluorescent material contained in the sintered body and the excitation light transmitted through the sintered body, and the ratio at which the excitation light having a wavelength shorter than that of the light wavelength-converted by the fluorescent material contained in the sintered body transmitted through the sintered body was low, so that these light emitting devices emitted light having a low relative luminous flux.

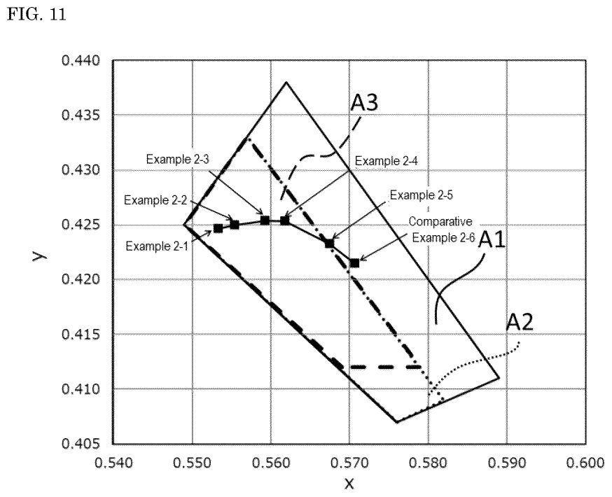

FIG. 11 is a chromaticity diagram of the CIE1931 color system showing the areas A1, A2, and A3, as well as the chromaticity coordinates (x, y) of the light emission of the light emitting device using the sintered body according to each of Examples 2-1 to 2-5 and Comparative Example 2-6. As shown in FIG. 11, the light emitting device using the sintered body according to each of Examples 2-1 to 2-5 emitted light having an amber color within the area A3 on the even shorter wavelength side of the area A1.

As shown in FIG. 11, each of the light emitting devices using the sintered bodies according to Comparative Example 2-6 emitted light having a color within the area A1 but outside of the areas A2 and A3.

The sintered body used in the light emitting device according to each of Examples 2-1 to 2-5 contained the nitride fluorescent material having the composition represented by the formula (I), wherein in the formula (I), M² was Eu, w satisfied 0.001≤w<0.0035, more specifically 0.002≤w≤0.003, and the thickness of the sintered body was 130 μm or more and 183 μm or less. In each of the light emitting devices according to Examples 2-1 to 2-5 using these sintered bodies, the excitation light having a wavelength shorter than that of the light wavelength-converted by the fluorescent material contained in the sintered body was transmitted through the sintered body, so that light emitted from the sintered body, including light wavelength-converted from the excitation light by the fluorescent material contained in the sintered body and the excitation light transmitted through the sintered body, had an emission spectrum in which an integral value ratio Z2/Z1 was 0.005 or more, and thus light having a high relative luminous flux was emitted.

The sintered body used in the light emitting device according to Comparative Example 2-6 contained the nitride fluorescent material having the composition represented by the formula (I), wherein in the formula (I), M² was Eu, and w satisfied 0.001≤w<0.0035, more specifically 0.002≤w≤0.003, but the thickness of the sintered body exceeded 183 μm to obtain the desired color of light. The light emitting device according to Comparative Example 2-6 included a sintered body having a thickness exceeding 183 μm, which allowed the ratio of the excitation light transmitted through the sintered body to be low and allowed the light emitted from the sintered body, including light wavelength-converted from the excitation light by the fluorescent material contained in the sintered body and the excitation light transmitted through the sintered body, to have an light emission spectrum in which the integral value ratio Z2/Z1 was less than 0.005, thereby emitted light having a low relative luminous flux.

### Examples 3-1 to 3-3

A sintered body was obtained in the same or similar manner as in Examples 1-1 to 1-3, except that the nitride fluorescent material 3 was used, and the resulting sintered body was processed to have each of the thicknesses shown in Table 8 to obtain a sintered body according to each of Examples 3-1 to 3-3. Each sintered body was disposed at a location to be irradiated with light emitted from a light emitting element (LED) configured to emit excitation light having a light emission peak wavelength of 450 nm and an output of 1,300 mW/mm² or more and 6,000 mW/mm² or less, specifically 1,300 mW/mm² or more and 1,500 mW/mm² or less, to produce a light emitting device for testing. The light emitting device according to each of Examples 3-1 to 3-3 was subjected to the above measurements. The results are shown in Table 8.

TABLE 8

| | | | Light emitting device | | | | | | | | |
|---|---|---|---|---|---|---|---|---|---|---|---|
| | | | | | Integral | Integral | | | | | |
| | Sintered body | | | | value | value | Integral | Relative | | | |
| | | Relative | Chromaticity | | 500 nm- | 400 nm- | value | luminous | | | |
| Nitride fluorescent material 3 | Thickness | density | coordinates | | 800 nm | 500 nm | ratio | flux | Area | Area | Area |
| (Ba [symbol] Sr [symbol] Eu [symbol] ) [symbol] Si [symbol] N [symbol] | (μm) | (%) | x | y | Z1 | Z2 | Z2/Z1 | (%) | A1 | A2 | A3 |
| Example 3-1 | 103 | 99.4 | 0.5720 | 0.5112 | 116.885 | 1.31 [symbol] | 0.0113 | 109.0 | IN | IN | OUT |
| Example 3-2 | 116 | 9 [symbol] .7 | 0.5767 | 0.4105 | 11 [symbol] .582 | 1.007 | 0.00 [symbol] | 104.3 | IN | IN | OUT |
| Example 3-3 | 123 | 9 [symbol] .2 | 0. [symbol] 06 | 0.4096 | 115.971 | 0.669 | 0.005 [symbol] | 100.0 | IN | IN | OUT |

[symbol]

indicates data missing or illegible when filed

The light emitting device using the sintered body according to each of Examples 3-1 to 3-3 emitted light having a color within the area A1 and an integral value ratio Z2/Z1 of 0.005 or more in the light emission spectrum of the light emitted from the sintered body including light obtained by wavelength-converting the excitation light by the fluorescent material contained in the sintered body and the excitation light transmitted through the sintered body, and the excitation light having a wavelength shorter than that of the light wavelength converted by the fluorescent material contained in the sintered body was transmitted through the sintered body. The light emitting device according to each of Examples 3-1 to 3-3 emitted light having an amber color on the short wavelength side of the area A1 and having a high relative luminous flux.

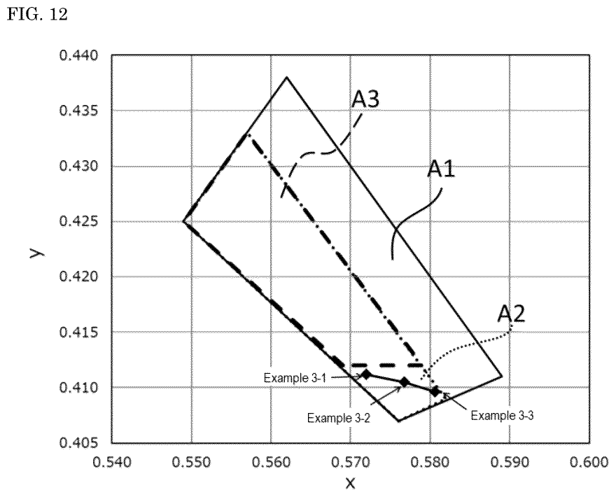

FIG. 12 is a chromaticity diagram of the CIE1931 color system showing the areas A1, A2, and A3, as well as the chromaticity coordinates (x, y) of the light emission of the light emitting device using the sintered body according to each of Examples 3-1 to 3-3. As shown in FIG. 12, the light emitting device using the sintered body according to each of Examples 3-1 to 3-3 emitted light having an amber color within the area A2, which is the area to the left of the sixth straight line connecting the point 2a′ (x=0.557, y=0.433) and the point 3a′ (x=0.582, y=0.409) within the area A1 in the chromaticity diagram of the CIE1931 color system.

The sintered body used in the light emitting device according to each of Examples 3-1 to 3-3 contained the nitride fluorescent material having the composition represented by the formula (I), wherein in the formula (I), M² was Eu, w satisfied 0.001≤w<0.005, more specifically 0.003≤w≤0.0045, and the thickness of the sintered body was 80 μm or more and 200 μm or less, more specifically 100 μm or more and 200 μm or less. In the light emitting devices according to Examples 3-1 to 3-3 using these sintered bodies, the excitation light having a wavelength shorter than that of the light wavelength-converted by the fluorescent material contained in the sintered body was transmitted through the sintered body, so as to have an integral value ratio Z2/Z1 of 0.005 or more in the light emission spectrum of the light emitted from the sintered body including light obtained by wavelength converting the excitation light by the fluorescent material contained in the sintered body and the excitation light transmitted through the sintered body, thereby emitting light having a high relative luminous flux.

### Examples 4-1 to 4-3 and Comparative Examples 4-4 and 4-5

A sintered body was obtained in the same or similar manner as in Examples 1-1 to 1-3, except that the nitride fluorescent material 4 was used, and the resulting sintered body was processed to have each of the thicknesses shown in Table 9 to obtain a sintered body according to each of Examples 4-1 to 4-3 and Comparative Examples 4-4 and 4-5. Each sintered body was disposed at a location irradiated with light emitted from a light emitting element (LED) irradiating excitation light having a light emission peak wavelength of 450 nm and an output of 1,300 mW/mm² or more and 6,000 mW/mm² or less, specifically 1,300 mW/mm² or more and 1,500 mW/mm² or less, to produce a light emitting device for testing. The light emitting device according to each of Examples 4-1 to 4-3 and Comparative Examples 4-4 and 4-5 was subjected to the above measurements. The results are shown in Table 9.

TABLE 9

| | | | Light emitting device | | | | | | | | |
|---|---|---|---|---|---|---|---|---|---|---|---|
| | | | | | Integral | Integral | | | | | |
| | Sintered body | | | | value | value | Integral | Relative | | | |
| | | Relative | Chromaticity | | 500 nm- | 400 nm- | value | luminous | | | |
| Nitride fluorescent material 4 | Thickness | density | coordinates | | 800 nm | 500 nm | ratio | flux | Area | Area | Area |
| (Ba [symbol] Sr [symbol] Eu [symbol] ) [symbol] Si [symbol] N [symbol] | (μm) | (%) | x | y | Z1 | Z2 | Z2/Z1 | (%) | A1 | A2 | A3 |
| Example 4-1 | 142 | 97.1 | 0.5 [symbol] 0 | 0.41 [symbol] 0 | 116.58 [symbol] | 1.27 [symbol] | 0.0110 | 103.3 | IN | IN | IN |
| Example 4-2 | 153 | 97.1 | 0.5 [symbol] 5 | 0.41 [symbol] 5 | 117.14 [symbol] | 1.130 | 0.0096 | 104.7 | IN | IN | IN |
| Example 4-3 | 173 | 97.9 | 0.5753 | 0.4147 | 115.907 | 0.663 | 0.0057 | 100.0 | IN | IN | IN |
| Comparative Example 4-4 | 1 [symbol] 4 | 97.2 | 0.57 [symbol] | 0.412 [symbol] | 115. [symbol] 44 | 0.515 | 0.0045 | 91. [symbol] | IN | OUT | OUT |
| Comparative Example 4-5 | 196 | 97.7 | 0.5 [symbol] 10 | 0.4115 | 114.99 [symbol] | 0.438 | 0.0038 | 93.0 | IN | OUT | OUT |

[symbol]

indicates data missing or illegible when filed

The light emitting device using the sintered body according to each of Examples 4-1 to 4-3 emitted light having a color within the area A1 and an integral value ratio Z2/Z1 of 0.005 or more in the light emission spectrum of the light emitted from the sintered body including light obtained by wavelength-converting the excitation light by the fluorescent material contained in the sintered body and the excitation light transmitted through the sintered body, and the excitation light having a wavelength shorter than that of the light wavelength-converted by the sintered body was transmitted through the sintered body. The light emitting device according to each of Examples 4-1 to 4-3 emitted light having an amber color on the short wavelength side of the area A1 and having a high relative luminous flux.

The light emitting device using the sintered body according to each of Comparative Examples 4-4 and 4-5 emitted light having a color within the area A1. However, the integral value ratio Z2/Z1 was less than 0.005 in the light emission spectrum of the light emitted from the sintered body including light obtained by wavelength-converting the excitation light by the fluorescent material contained in the sintered body and the excitation light transmitted through the sintered body, and the ratio at which the excitation light having a wavelength shorter than that of the light wavelength-converted by the sintered body transmitted through the sintered body was low, thereby emitting light having a low relative luminous flux.

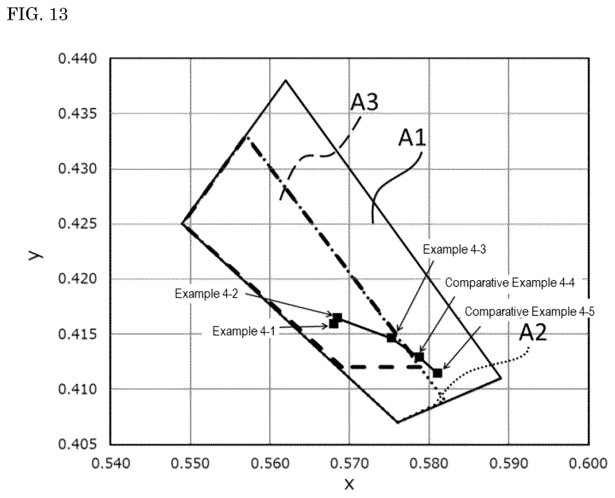

FIG. 13 is a chromaticity diagram of the CIE1931 color system showing the areas A1, A2, and A3, as well as the chromaticity coordinates (x, y) of the light emission of the light emitting device according to each of Examples 4-1 to 4-3 and Comparative Examples 4-4 and 4-5. As shown in FIG. 13, the light emitting device using the sintered body according to each of Examples 4-1 to 4-3 emitted light having an amber color within the area A3 on the even shorter wavelength side of the area A1.

As shown in FIG. 13, the light emitting device using the sintered body according to each of Comparative Examples 4-4 and 4-5 emitted light having a color within the area A1 but outside of the areas A2 and A3.

The sintered body used in the light emitting device according to each of Examples 4-1 to 4-3 contained the nitride fluorescent material having the composition represented by the formula (I), wherein in the formula (I), M² was Eu, w satisfied 0.001≤w<0.0035, more specifically 0.002≤w≤0.003, and the thickness of the sintered body was 130 μm or more and 183 μm or less. In the light emitting devices according to Examples 4-1 to 4-3 using these sintered bodies, the excitation light having a wavelength shorter than that of the light wavelength-converted by the fluorescent material contained in the sintered body was transmitted through the sintered body, so as to have an integral value ratio Z2/Z1 of 0.005 or more in the light emission spectrum of the sintered body including light obtained by wavelength converting the excitation light by the fluorescent material contained in the sintered body and the excitation light transmitted through the sintered body, thereby emitting light having a high relative luminous flux.

The sintered body used in the light emitting device according to each of Comparative Examples 4-4 and 4-5 contained the nitride fluorescent material having the composition represented by the formula (I), wherein in the formula (I), M² was Eu, and w satisfied 0.002≤w<0.0035, more specifically 0.002≤w≤0.003, but the thickness of the sintered body was thicker than 183 μm. Since the light emitting device according to each of Comparative Examples 4-4 and 4-5 included a sintered body having a thickness exceeding 183 μm, the ratio of the excitation light transmitted through the sintered body was low, and the integral value ratio Z2/Z1 was less than 0.005 in the light emission spectrum of the light emitted from the sintered body including light obtained by wavelength-converting the excitation light by the fluorescent material contained in the sintered body and the excitation light transmitted through the sintered body, thereby emitting light having a low relative luminous flux.

### Examples 5-1 to 5-4

A sintered body was obtained in the same or similar manner as in Examples 1-1 to 1-3, except that the nitride fluorescent material 5 was used, and the resulting sintered body was processed to have each of the thicknesses shown in Table 10 to obtain a sintered body according to each of Examples 5-1 to 5-4. Each sintered body was disposed at a location irradiated with light emitted from a light emitting element (LED) irradiating excitation light having a light emission peak wavelength of 450 nm and an output of 1,300 mW/mm² or more and 6,000 mW/mm² or less, specifically 1,300 mW/mm² or more and 1,500 mW/mm² or less, to produce a light emitting device for testing. The light emitting device according to each of Examples 5-1 to 5-4 was subjected to the above measurements. The results are shown in Table 10.

TABLE 10

| | | | Light emitting device | | | | | | | | |
|---|---|---|---|---|---|---|---|---|---|---|---|
| | | | | | Integral | Integral | | | | | |
| | Sintered body | | | | value | value | Integral | Relative | | | |
| | | Relative | Chromaticity | | 500 nm- | 400 nm- | value | luminous | | | |
| Nitride fluorescent material 5 | Thickness | density | coordinates | | 800 nm | 500 nm | ratio | flux | Area | Area | Area |
| (Ba [symbol] Sr [symbol] Eu [symbol] ) [symbol] Si [symbol] N [symbol] | (μm) | (%) | x | y | Z1 | Z2 | Z2/Z1 | (%) | A1 | A2 | A3 |
| Example 5-1 | 1 [symbol] 2 | 99.5 | 0. [symbol] | 0.4223 | 117.1 [symbol] 1 | 1. [symbol] 00 | 0.013 [symbol] | 131.0 | IN | IN | IN |
| Example 5-2 | 201 | 99.5 | 0.5 [symbol] 07 | 0.422 [symbol] | 117.0 [symbol] | 1.312 | 0.0113 | 122.4 | IN | IN | IN |
| Example 5-3 | 21 [symbol] | 99.1 | 0.5 [symbol] 29 | 0.422 [symbol] | 116.534 | 1.0 [symbol] 1 | 0.0094 | 120.6 | IN | IN | IN |
| Example 5-4 | 230 | 99.1 | 0.5714 | 0.41 [symbol] 9 | 115. [symbol] 41 | 0.702 | 0.0061 | 100.0 | IN | IN | IN |

[symbol]

indicates data missing or illegible when filed

When the light emitting device using the sintered body according to each of Examples 5-1 to 5-4 were irradiated with excitation light, light including light wavelength-converted from the excitation light by the fluorescent material contained in the sintered body and the excitation light transmitted through the sintered body was emitted from the sintered body of each of the light emitting devices, and the light emitted from the sintered body had a color within the area A1 and had an emission spectrum in which an integral value ratio Z2/Z1 was 0.005 or more. In these light emitting devices, the excitation light having a wavelength shorter than that of the light wavelength-converted by the fluorescent material contained in the sintered body was transmitted through the sintered body. The light emitting device according to each of Examples 5-1 to 5-4 emitted light having an amber color on the short wavelength side of the area A1 and having a high relative luminous flux.

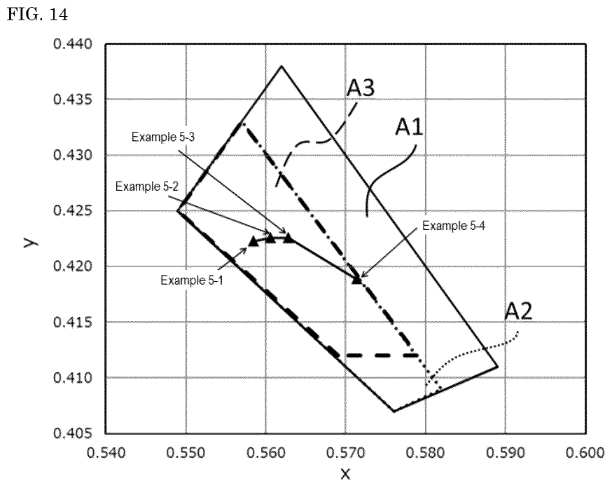

FIG. 14 is a chromaticity diagram of the CIE1931 color system showing the areas A1, A2, and A3, as well as the chromaticity coordinates (x, y) of the light emission of the light emitting device using the sintered body according to each of Examples 5-1 to 5-4. As shown in FIG. 14, the light emitting device according to each of Examples 5-1 to 5-4 emitted light having an amber color within the area A3 on the even shorter wavelength side of the area A1.

The sintered body used in the light emitting device according to each of Examples 5-1 to 5-4 contained the nitride fluorescent material having the composition represented by the formula (I), wherein in the formula (I), M² was Eu, w satisfied 0.001≤w<0.0025, more specifically 0.001≤w≤0.002, and the thickness of the sintered body was 150 μm or more and 250 μm or less, more specifically 180 μm or more and 250 μm or less. In the light emitting devices according to Examples 5-1 to 5-4 using these sintered bodies, the excitation light having a wavelength shorter than that of the light wavelength-converted by the fluorescent material contained in the sintered body was transmitted through the sintered body, so that light emitted from the sintered body, including light wavelength-converted from the excitation light by the fluorescent material contained in the sintered body and the excitation light transmitted through the sintered body, had an emission spectrum in which an integral value ratio Z2/Z1 was 0.005 or more, and thus light having a high relative luminous flux was emitted.

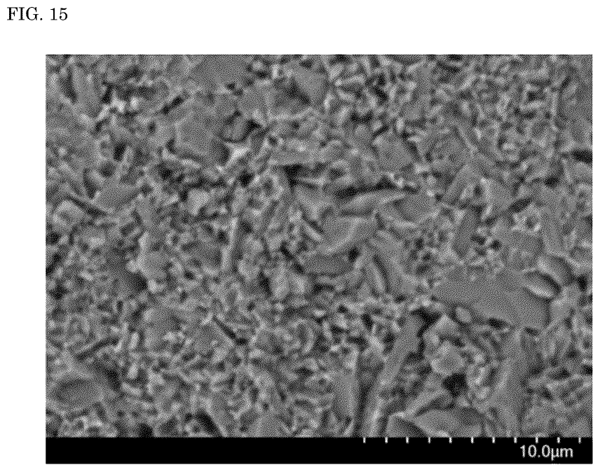

FIG. 15 is an SEM micrograph of the fractured surface of the sintered body used in the light emitting device according to Example 5-1. As shown in FIG. 15, individual fluorescent material particles were observed on the fractured surface of the sintered body used in the light emitting device according to Example 5-1, wherein the long diameter of the fluorescent material particles was 0.1 μm or more and 20 μm or less. In the SEM micrograph of the fractured surface of the sintered body used in the light emitting device according to Example 5-1, the long diameter of each fluorescent material particle, which is the longest diameter measured from one end of the outline of the fluorescent material particle where the outline can be observed to the other end of the fluorescent material particle through the inside of the fluorescent material particle, was approximately 10 μm at the largest. In the micrograph shown in FIG. 15, it was observed that the fluorescent material particles in the sintered body were larger than the raw fluorescent material particles, and the particle growth of the fluorescent material particles was facilitated.

### Examples 6-1 to 6-4

A sintered body was obtained in the same or similar manner as in Examples 1-1 to 1-3, except that the nitride fluorescent material 6 was used, and the resulting sintered body was processed to have each of the thicknesses shown in Table 11 to obtain a sintered body according to each of Examples 6-1 to 6-4. Each sintered body was disposed at a location irradiated with light emitted from a light emitting element (LED) irradiating excitation light having a light emission peak wavelength of 450 nm and an output of 1,300 mW/mm² or more and 6,000 mW/mm² or less, specifically 1,300 mW/mm² or more and 1,500 mW/mm² or less, to produce a light emitting device for testing. The light emitting device for testing according to each of Examples 6-1 to 6-4 was subjected to the above measurements. The results are shown in Table 11.

TABLE 11

| | | | Light emitting device | | | | | | | | |
|---|---|---|---|---|---|---|---|---|---|---|---|
| | | | | | Integral | Integral | | | | | |
| | Sintered body | | | | value | value | Integral | Relative | | | |
| | | Relative | Chromaticity | | 500 nm- | 400 nm- | value | luminous | | | |
| Nitride fluorescent material 6 | Thickness | density | coordinates | | 800 nm | 500 nm | ratio | flux | Area | Area | Area |
| (Ba [symbol] Sr [symbol] Eu [symbol] ) [symbol] Si [symbol] N [symbol] | (μm) | (%) | x | y | Z1 | Z2 | Z2/Z1 | (%) | A1 | A2 | A3 |
| Example 6-1 | 135 | 98.1 | 0.5509 | 0.4243 | 11 [symbol] | 2.1 [symbol] | 0.01 [symbol] 5 | 10 [symbol] | IN | IN | IN |
| Example 6-2 | 141 | 98.3 | 0.5562 | 0.4254 | 115.929 | 1.500 | 0.0129 | 105.6 | IN | IN | IN |
| Example 6-3 | 155 | 9 [symbol] .0 | 0.5600 | 0.42 [symbol] | 115 [symbol] 04 | 1.133 | 0.009 [symbol] | 102.1 | IN | IN | IN |
| Example 6-4 | 1 [symbol] 2 | 97.4 | 0.5675 | 0.423 [symbol] | 114.3 [symbol] 7 | 0.575 | 0.0050 | 100.0 | IN | IN | IN |

[symbol]

indicates data missing or illegible when filed

The light emitting device using the sintered body according to each of Examples 6-1 to 6-4 emitted light having a color within the area A1 and an integral value ratio Z2/Z1 of 0.005 or more in the light emission spectrum of the light emitted from the sintered body including light obtained by wavelength-converting the excitation light by the fluorescent material contained in the sintered body and the excitation light transmitted through the sintered body, and the excitation light having a wavelength shorter than that of the light wavelength-converted by the fluorescent material contained in the sintered body was transmitted through the sintered body. The light emitting device according to each of Examples 6-1 to 6-4 emitted light having an amber color on the short wavelength side of the area A1 and having a high relative luminous flux.

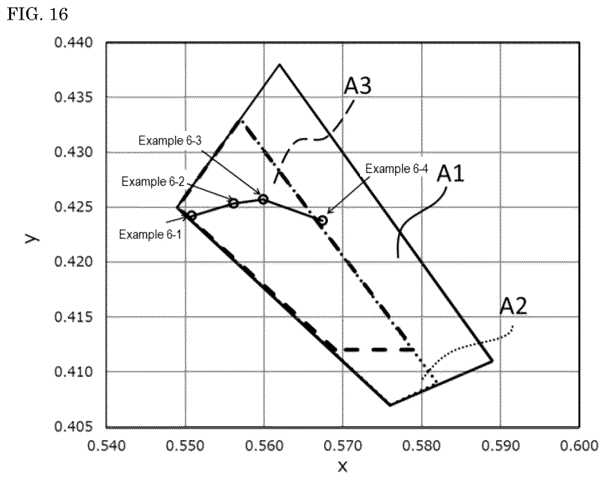

FIG. 16 is a chromaticity diagram of the CIE1931 color system showing the areas A1, A2, and A3, as well as the chromaticity coordinates (x, y) of the light emission of the light emitting device using the sintered body according to each of Examples 6-1 to 6-4. As shown in FIG. 16, the light emitting device according to each of Examples 6-1 to 6-4 emitted light having an amber color within the area A3 on the even shorter wavelength side of the area A1.

The sintered body used in the light emitting device according to each of Examples 6-1 to 6-4 contained the nitride fluorescent material having the composition represented by the formula (I), wherein in the formula (I), M² was Eu, w satisfied 0.001≤w<0.005, more specifically 0.003≤w≤0.0045, and the thickness of the sintered body was 80 μm or more and 250 μm or less, more specifically 100 μm or more and 200 μm or less. In the light emitting devices according to Examples 6-1 to 6-4 using these sintered bodies, the excitation light having a wavelength shorter than that of the light wavelength-converted by the fluorescent material contained in the sintered body was transmitted through the sintered body, so that light emitted from the sintered body, including light wavelength-converted from the excitation light by the fluorescent material contained in the sintered body and the excitation light transmitted through the sintered body, had an emission spectrum in which an integral value ratio Z2/Z1 was 0.005 or more, and thus light having a high relative luminous flux was emitted.

The sintered body according to the present disclosure can be used as a wavelength conversion member capable of converting the wavelength of light emitted from an LED or an LD. The light emitting device using the sintered body can be used for applications such as on-vehicle lighting, general lighting, backlighting for liquid crystal display devices, illuminations, and light sources for projectors. The sintered body used in the light emitting device emits light upon irradiation with excitation light and can also be used as a material for solid scintillators.

What is claimed is:

1. A sintered body comprising
a fluorescent material being at least one selected from the group consisting of:
a nitride fluorescent material having a composition represented by the following formula (I) and
an α-SiAlON fluorescent material having a composition represented by the following formula (II),
(Ba_{1-u-w}M¹ᵤM²_{w})₂Si₅N₈ (I),
wherein M¹ represents at least one element selected from the group consisting of Sr, Ca, and Mg, M² represents at least one element selected from the group consisting of Eu, Ce, Tb, and Mn, and u and w satisfy 0<u≤0.5 and 0.001≤w<0.5; and
M³_{q}Si₁₂₋₍ᵣ₊ₛ₎Alᵣ₊ₛOₛN₁₆₋ₛ:Euₜ (II),
wherein M³ represents at least one element selected from the group consisting of Li, Mg, Ca, Sr, Y, and lanthanide elements (excluding La and Ce), and q, r, s, and t satisfy 0<q≤2.0, 2.0≤r≤6.0, 0≤s≤1.0, and 0.001≤t≤0.5;
wherein the sintered body is configured to emit light having a color in an area A1 in the chromaticity diagram of the CIE 1931 color system upon irradiation with excitation light, the area A1 being defined by a first straight line connecting a point 1a and a point 2a, a second straight line connecting the point 2a and a point 3a, a third straight line connecting the point 3a and a point 4a, and a fourth straight line connecting the point 4a and the point 1a wherein the point 1a, the point 2a, the point 3a, and the point 4a have the chromaticity coordinates (x, y) being (x=0.549, y=0.425), (x=0.562, y=0.438), (x=0.589, y=0.411), and (x=0.576, y=0.407), respectively, in the chromaticity diagram of the CIE 1931 color system,
wherein, upon irradiation with excitation light having a light emission peak wavelength that is 450 nm and an output that is 1,300 mW/mm² or more and 6,000 mW/mm² or less, the sintered body emits light including light wavelength-converted from the excitation light by the fluorescent material contained in the sintered body and the excitation light transmitted through the sintered body, and the light emitted from the sintered body has a light emission spectrum in which an integral value ratio Z2/Z1 of a second integral value Z2 of light emission intensities in a wavelength range of 400 nm or more and 500 nm or less to a first integral value Z1 of light emission intensities in a wavelength range of more than 500 nm and 800 nm or less is 0.005 or more.

2. The sintered body according to claim 1, wherein the integral value ratio Z2/Z1 is 0.008 or more.

3. The sintered body according to claim 1, wherein the integral value ratio Z2/Z1 is 0.01 or more and 0.04 or less.

4. The sintered body according to claim 1, wherein the sintered body is formed by calcining fluorescent material particles having an average particle diameter Db, as measured by a Fischer Sub-Sieve Sizer method, that is less than 1 μm.

5. The sintered body according to claim 1, wherein the sintered body is formed by calcining fluorescent material particles having a particle diameter ratio Db/Dm of an average particle diameter Db, as measured by the Fisher Sub-Sieve Sizer method, to a volume median diameter Dm, as measured by a laser diffraction particle size distribution measurement method, that is 0.45 or less.

6. The sintered body according to claim 1, wherein the sintered body has a relative density that is 97% or more.

7. The sintered body according to claim 1, wherein the sintered body has a thickness that is 30 μm or more and 300 μm or less.

8. The sintered body according to claim 1, wherein
the sintered body is adapted to emit light having a color in an area A2 within the area A1 in the chromaticity diagram of the CIE 1931 color system upon irradiation with excitation light, and
when the chromaticity coordinates (x=0.549, y=0.425), (x=0.557, y=0.433), (x=0.582, y=0.409), and (x=0.576, y=0.407) are defined as a point 1a, a point 2a′, a point 3a′, and a point 4a, respectively, the area A2 is surrounded by a fifth straight line connecting the point 1a and the point 2a′, a sixth straight line connecting the point 2a′ and the point 3a′, a seventh straight line connecting the point 3a′ and the point 4a, and a eighth straight line connecting the point 4a and the point 1a.

9. The sintered body according to claim 1, wherein
the sintered body is adapted to emit light having a color in an area A3 within the area A1 in the chromaticity diagram of the CIE 1931 color system upon irradiation with excitation light, and
when the chromaticity coordinates (x=0.549, y=0.425), (x=0.557, y=0.433), (x=0.579, y=0.412), and (x=0.569, y=0.412) are defined as a point 1a, a point 2a′, a point 3a″, and a point 4a″, respectively, the area A3 is surrounded by a ninth straight line connecting the point 1a and the point 2a′, a tenth straight line connecting the point 2a′ and the point 3a″, a eleventh straight line connecting the point 3a″ and the point 4a″, and a twelfth straight line connecting the point 4a″ and the point 1a.

10. The sintered body according to claim 1, wherein
the sintered body has a thickness that is 50 μm or more and 250 μm or less,
the sintered body comprises a first nitride fluorescent having a composition represented by the formula (I), and
in the formula (I), M² is Eu, and w satisfies 0.001≤w<0.01.

11. The sintered body according to claim 1, wherein
the sintered body has a thickness of 80 μm or more and 250 μm or less,
the sintered body comprises the first nitride fluorescent having the composition represented by the formula (I), and
in the formula (I), M² is Eu, and w satisfies 0.001≤w<0.005.

12. The sintered body according to claim 1, wherein
the sintered body has a thickness that 100 μm or more and 200 μm or less,
the sintered body comprises the first nitride fluorescent having the composition represented by the formula (I), and
in the formula (I), M² is Eu, and w satisfies 0.003≤w≤0.0045.

13. The sintered body according to claim 1, wherein
the sintered body has a thickness that is 120 μm or more and 250 μm or less,
the sintered body comprises the first nitride fluorescent having the composition represented by the formula (I), and
in the formula (I), M² is Eu, and w satisfies 0.001≤w<0.0035.

14. The sintered body according to claim 1, wherein
the sintered body has a thickness that is 130 μm or more and 183 μm or less,
the sintered body comprises the first nitride fluorescent having the composition represented by the formula (I), and
in the formula (I), M² is Eu, and w satisfies 0.002≤w≤0.003.

15. The sintered body according to claim 1, wherein
the sintered body has a thickness that is 150 μm or more and 250 μm or less,
the sintered body comprises the first nitride fluorescent having the composition represented by the formula (I), and
in the formula (I), M² is Eu, and w satisfies 0.001≤w<0.0025.

16. The sintered body according to claim 1, wherein
the sintered body has a thickness that is 180 μm or more and 250 μm or less,
the sintered body comprises the first nitride fluorescent having the composition represented by the formula (I), and
in the formula (I), M² is Eu, and w satisfies 0.001≤w≤0.002.

17. The sintered body according to claim 10, wherein
the sintered body comprises the first nitride fluorescent having the composition represented by the formula (I), and
in the formula (I), u satisfies 0.25≤u≤0.45.

18. A light emitting device comprising:
an excitation light source configured to emit light having a light emission peak wavelength in a range of 380 nm or more and 570 nm or less, and
the sintered body according to claim 1.
